(19) United States
(12) Patent Application Publication
(10) Pub. No.: US 2026/0128066 A1
(43) Pub. Date: May 7, 2026

(54) SEMICONDUCTOR MEMORY DEVICE

(71) Applicant: Kioxia Corporation, Tokyo (JP)

(72) Inventors: Shotaro HADA, Kitakami (JP); Shigeki KOBAYASHI, Kamakura (JP); Hiroshi SHINOHARA, Yokosuka (JP); Hiroyasu TANAKA, Yokohama (JP)

(73) Assignee: Kioxia Corporation, Tokyo (JP)

(21) Appl. No.: 19/317,226

(22) Filed: Sep. 3, 2025

(30) Foreign Application Priority Data
Nov. 5, 2024 (JP) 2024-193382

(51) Int. Cl. G11C 5/06; G11C 16/04; G11C 16/14; G11C 16/26; G11C 16/30; H01L 23/00; H01L 25/18; H10B 41/10; H10B 41/27; H10B 41/35; H10B 41/41; H10B 43/10; H10B 43/27; H10B 43/35; H10B 43/40; H10D 80/30

(52) U.S. Cl. CPC G11C 5/063; G11C 16/0483; G11C 16/14; G11C 16/26; G11C 16/30; H10B 41/10; H10B 41/27; H10B 41/35; H10B 41/41; H10B 43/10; H10B 43/27; H10B 43/35; H10B 43/40; H10D 80/30; H10W 90/00; H10W 90/792

(57) ABSTRACT

A semiconductor memory device includes a semiconductor substrate and a memory cell array arranged in a first direction. The memory cell array includes a first region and a second region arranged in a second direction intersecting with the first direction, and a plurality of conductive layers include a first conductive layer, a third conducive layer and a second conductive layer in order from the closest to the semiconductor substrate. The first conductive layer is divided in the second direction to constitute a first divided layer and a second divided layer. The second conductive layer is divided in the second direction to constitute a third divided layer and a fourth divided layer. The third conductive layer is continuous over the first region and the second region. A plurality of wirings include a first wiring in the first region and a second wiring in the second region.

### CROSS-REFERENCE TO RELATED APPLICATIONS

This application is based upon and claims the benefit of Japanese Patent Application No. 2024-193382, filed on Nov. 5, 2024, the entire contents of which are incorporated herein by reference.

### BACKGROUND

### Field

Embodiments described herein relate generally to a semiconductor memory device.

### Description of the Related Art

There has been known a semiconductor memory device that includes a substrate, a plurality of conductive layers stacked in a direction intersecting with a surface of this substrate, a semiconductor layer facing these plurality of conductive layers, and a gate insulating layer provided between the conductive layers and the semiconductor layer. The gate insulating layer includes a memory portion that can store data, for example, an insulating electric charge accumulating layer of silicon nitride (SiN) or the like or a conductive electric charge accumulating layer such as a floating gate.

### BRIEF DESCRIPTION OF THE DRAWINGS

FIG. 1 is a schematic block diagram illustrating a configuration of a memory die MD;

FIG. 2 is a schematic circuit diagram illustrating a configuration of a part of the memory die MD;

FIG. 3 is a schematic circuit diagram illustrating a configuration of a row decoder RD;

FIG. 4 is a schematic circuit diagram illustrating a configuration of a sense amplifier module SAM;

FIG. 5 is a schematic exploded perspective view illustrating an exemplary configuration of a semiconductor memory device according to a first embodiment;

FIG. 6 is a schematic perspective view illustrating an exemplary configuration of a chip C_{M} and a chip C_{P};

FIG. 7 is a schematic bottom view of illustrating a configuration of a part of the chip C_{M} when viewed in a direction of an arrow A in FIG. 6;

FIG. 8 is a schematic cross-sectional view of a part of the chip C_{M} taken along line B-B′ and viewed in an arrow direction in FIG. 7;

FIG. 9 is a schematic cross-sectional view of a part of the chip C_{M} taken along line C-C′ and viewed in an arrow direction in FIG. 7;

FIG. 10 is a schematic cross-sectional view illustrating an enlarged part D in FIG. 9;

FIG. 11 is a diagram schematically illustrating voltages applied to respective portions in a read operation of the memory die MD according to the first embodiment;

FIG. 12 is a diagram schematically illustrating voltages applied to respective portions in another read operation of the memory die MD according to the first embodiment;

FIG. 13 is a diagram schematically illustrating voltages applied to respective portions in another read operation of the memory die MD according to the first embodiment;

FIG. 14 is a diagram schematically illustrating voltages applied to respective portions in another read operation of the memory die MD according to the first embodiment;

FIG. 15 is a diagram schematically illustrating voltages applied to respective portions in a write operation of the memory die MD according to the first embodiment;

FIG. 16 is a diagram schematically illustrating voltages applied to respective portions in an erase operation of the memory die MD according to the first embodiment;

FIG. 17 is a cross-sectional view illustrating a schematic configuration of a semiconductor memory device according to a second embodiment;

FIG. 18 is a block diagram illustrating a schematic configuration of a row decoder RD used in the second embodiment;

FIG. 19 is a schematic exploded perspective view illustrating an exemplary configuration of a semiconductor memory device according to a third embodiment;

FIG. 20 is a schematic perspective view illustrating an exemplary configuration of a chip C_{M1}, a chip C_{M2}, and a chip C_{P};

FIG. 21 is a schematic circuit diagram illustrating a configuration of a part of the memory die MD;

FIG. 22 is a schematic circuit diagram illustrating a configuration of a row decoder RD;

FIG. 23 is a schematic block diagram illustrating a configuration of a sense amplifier module SAM;

FIG. 24 is a schematic bottom view illustrating a configuration of a part of the chips C_{M1} and C_{M2} when viewed in a direction of an arrow E in FIG. 20;

FIG. 25 is a schematic cross-sectional view of a part of the chips C_{M1} and C_{M2} taken along line F-F′ and viewed in an arrow direction in FIG. 24;

FIG. 26 is a schematic cross-sectional view of a part of the chips C_{M1} and C_{M2} taken along line G-G′ and viewed in an arrow direction in FIG. 24;

FIG. 27 is a diagram schematically illustrating voltages applied to respective portions of memory planes MP1, MP2 in a read operation of the memory die MD according to the third embodiment;

FIG. 28 is a diagram schematically illustrating voltages applied to respective portions of the memory planes MP1, MP2 in another read operation;

FIG. 29 is a diagram schematically illustrating voltages applied to respective portions of the memory planes MP1, MP2 in another read operation;

FIG. 30 is a diagram schematically illustrating voltages applied to respective portions of the memory planes MP1, MP2 in another read operation;

FIG. 31 is a diagram schematically illustrating voltages applied to respective portions in a write operation of the memory die MD according to the third embodiment;

FIG. 32 is a diagram schematically illustrating voltages applied to respective portions in an erase operation of the memory die MD according to the third embodiment; and

FIG. 33 is a schematic plan view for describing a semiconductor memory device according to a fourth embodiment when viewed in a direction of an arrow E in FIG. 20.

### DETAILED DESCRIPTION

A semiconductor memory device according to one embodiment comprises a semiconductor substrate and a memory cell array arranged at one side in a first direction intersecting with the semiconductor substrate with respect to the semiconductor substrate. The memory cell array includes: a plurality of conductive layers extending in a second direction intersecting with the first direction and arranged in the first direction; a plurality of semiconductor layers extending in the first direction, arranged in a direction intersecting with the first direction, and facing the plurality of conductive layers; respective gate insulating films provided between the plurality of semiconductor layers and the plurality of conductive layers; and a plurality of wirings extending in a third direction intersecting with the first direction and the second direction, arranged in the second direction, and electrically connected to one end side in the first direction of the semiconductor layers. The memory cell array includes a first region and a second region arranged in the second direction, and the plurality of conductive layers include: a first conductive layer closest to the semiconductor substrate; a second conductive layer farthest from the semiconductor substrate; and a third conductive layer provided between the first conductive layer and the second conductive layer. The first conductive layer is divided in the second direction to constitute a first divided layer positioned in the first region and a second divided layer positioned in the second region. The second conductive layer is divided in the second direction to constitute a third divided layer positioned in the first region and a fourth divided layer positioned in the second region. The third conductive layer is continuous over the first region and the second region. The plurality of wirings include a first wiring positioned in the first region and a second wiring positioned in the second region.

Next, the semiconductor memory devices according to embodiments are described in detail with reference to the drawings. The following embodiments are only examples, and not described for the purpose of limiting the present invention. The following drawings are schematic, and for convenience of description, a part of a configuration and the like is sometimes omitted. Parts common in a plurality of embodiments are attached by same reference numerals and their descriptions may be omitted.

In this specification, when referring to a “semiconductor memory device”, it may mean a memory die and may mean a memory system including a controller die, such as a memory chip, a memory card, and a Solid State Drive (SSD). Further, it may mean a configuration including a host computer, such as a smartphone, a tablet terminal, and a personal computer.

In this specification, when it is referred that a first configuration “is electrically connected” to a second configuration, the first configuration may be directly connected to the second configuration, and the first configuration may be connected to the second configuration via a wiring, a semiconductor member, a transistor, or the like. For example, when three transistors are connected in series, even when the second transistor is in an OFF state, the first transistor is “electrically connected” to the third transistor.

In this specification, when it is referred that the first configuration “is connected between” the second configuration and a third configuration, it may mean that the first configuration, the second configuration, and the third configuration are connected in series and the second configuration is connected to the third configuration via the first configuration.

In this specification, when it is referred that a circuit or the like “electrically conducts” two wirings or the like, it may mean, for example, that this circuit or the like includes a transistor or the like, this transistor or the like is disposed in a current path between the two wirings, and this transistor or the like enters an ON state.

In this specification, a direction parallel to an upper surface of the substrate is referred to as an X-direction, a direction parallel to the upper surface of the substrate and perpendicular to the X-direction is referred to as a Y-direction, and a direction perpendicular to the upper surface of the substrate is referred to as a Z-direction.

In this specification, a direction along a predetermined plane may be referred to as a first direction, a direction along this predetermined plane and intersecting with the first direction may be referred to as a second direction, and a direction intersecting with this predetermined plane may be referred to as a third direction. These first direction, second direction, and third direction may each correspond to any of the X-direction, the Y-direction, and the Z-direction and need not correspond to these directions.

In this specification, when referring to a “width”, a “length”, a “thickness”, or the like of a configuration, a member, or the like in a predetermined direction, this may mean a width, a length, a thickness, or the like in a cross-sectional surface or the like observed with a Scanning electron microscopy (SEM), a Transmission electron microscopy (TEM), or the like.

In this specification, when referring to a “wiring”, this may include a wiring, a via-contact electrode, a connecting portion for connecting a wiring to a via-contact electrode, a bonding electrode, or the like.

### First Embodiment

### Circuit Configuration of Memory Die MD

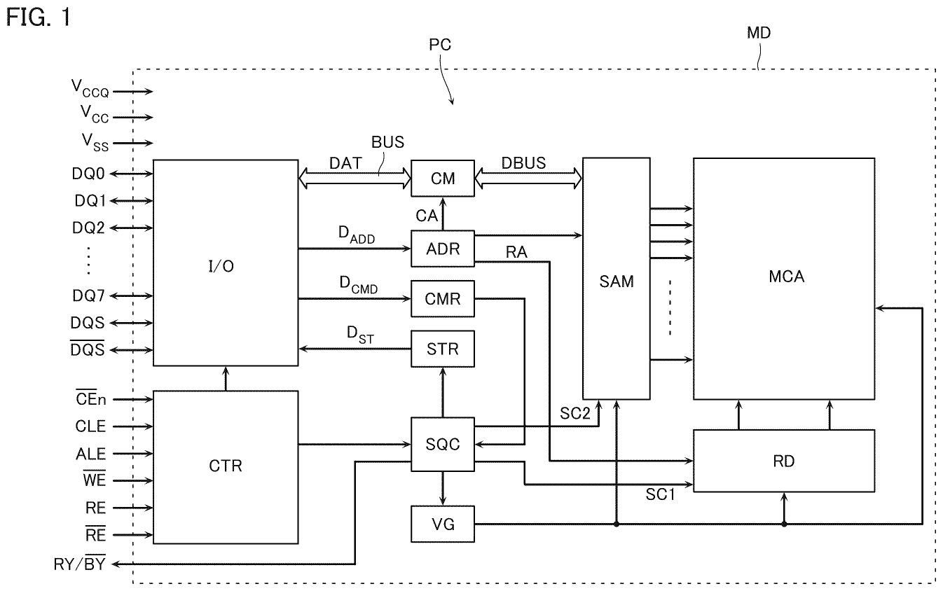

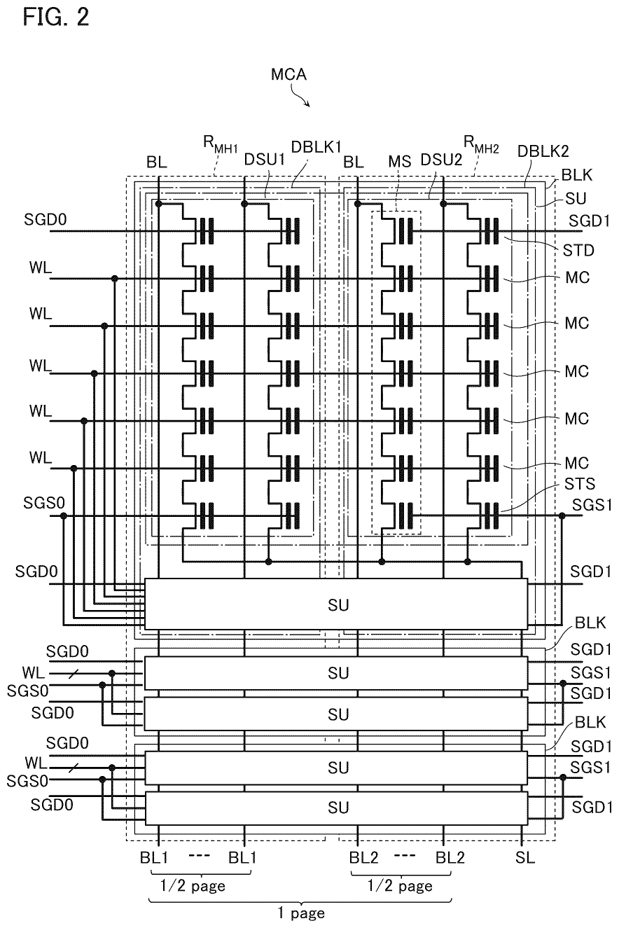

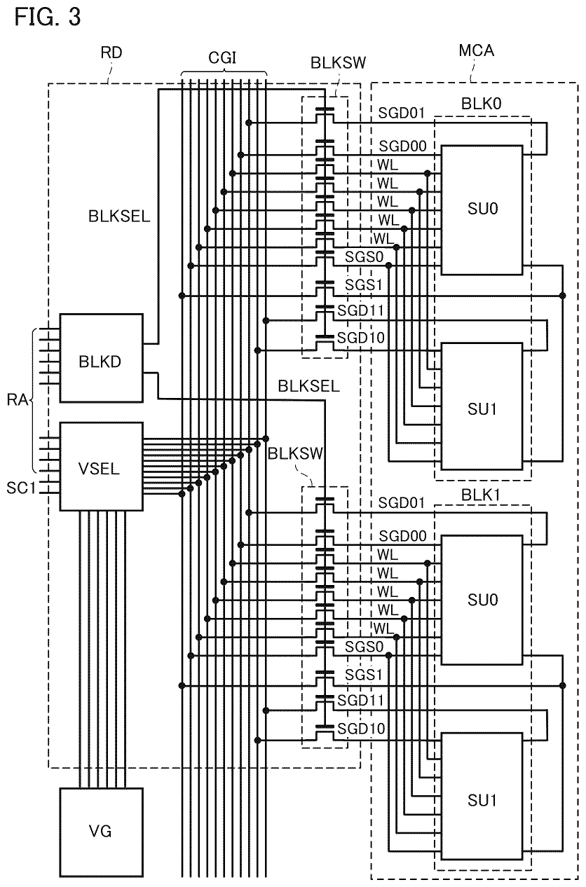

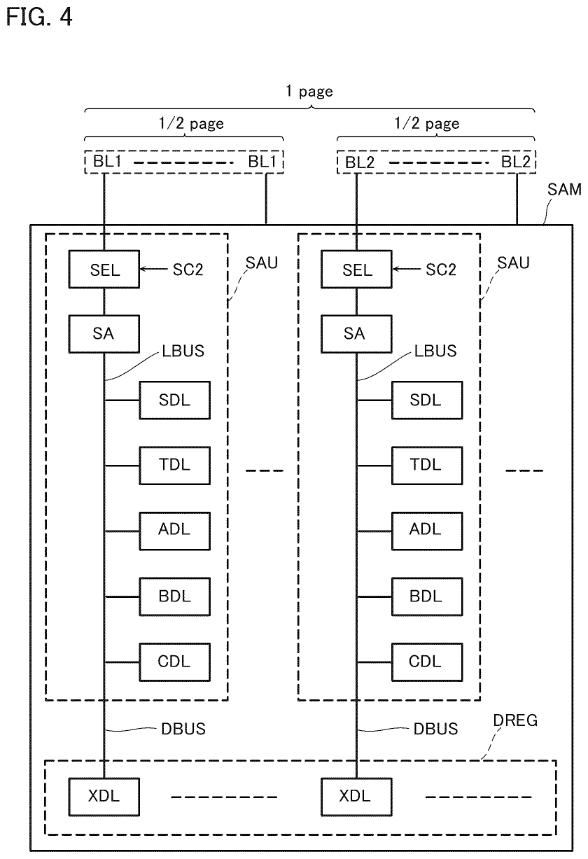

FIG. 1 is a schematic block diagram illustrating a configuration of a memory die MD according to the first embodiment. FIG. 2 is a schematic circuit diagram illustrating a configuration of a part of the memory die MD. FIG. 3 is a schematic circuit diagram illustrating a configuration of a row decoder RD. FIG. 4 is a schematic block diagram illustrating a configuration of a sense amplifier module SAM.

FIG. 1 illustrates a plurality of control terminals and the like. These plurality of control terminals are expressed as control terminals corresponding to high active signals (positive logic signals) in some cases. The plurality of control terminals are expressed as control terminals corresponding to low active signals (negative logic signals) in some cases. The plurality of control terminals are expressed as control terminals corresponding to both of the high active signals and the low active signals in some cases. In FIG. 1, reference signs of the control terminals corresponding to the low active signals include overlines (overbars). In this specification, a reference sign of the control terminal corresponding to the low active signal includes a slash (“/”). Note that the description in FIG. 1 is an example, and the specific aspect is appropriately adjustable. For example, a part of or all of the high active signals can be changed to the low active signals, or a part of or all of the low active signals can be changed to the high active signals.

As illustrated in FIG. 1, the memory die MD includes a memory cell array MCA and a peripheral circuit PC. The peripheral circuit PC includes a voltage generation circuit VG, the row decoder RD, the sense amplifier module SAM, and a sequencer SQC. The peripheral circuit PC includes a cache memory CM, an address register ADR, a command register CMR, and a status register STR. The peripheral circuit PC includes an input/output control circuit I/O and a logic circuit CTR.

### Circuit Configuration of Memory Cell Array MCA

As illustrated in FIG. 2, the memory cell array MCA includes a plurality of memory blocks BLK. Each of these plurality of memory blocks BLK includes a plurality of string units SU. Each of these plurality of string units SU includes a plurality of memory strings MS. The numbers of the memory blocks BLK, the string units SU, and the memory strings MS are not limited to the illustrated numbers. These plurality of memory strings MS have one ends each connected to the peripheral circuit PC via bit lines BL. These plurality of memory strings MS have the other ends each connected to the peripheral circuit PC via a common source line SL.

The memory cell array MCA is divided into a first memory region R_{MH1} and a second memory region R_{MH2} in an arrangement direction of a plurality of bit lines BL. Hereinafter, the memory block BLK, the string unit SU, and the bit line BL included in the first memory region R_{MH1} may be referred to as a first divided block DBLK1, a first divided string unit DSU1, and a first bit line BL1, respectively. The memory block BLK, the string unit SU, and the bit line BL included in the second memory region R_{MH2} may be referred to as a second divided block DBLK2, a second divided string unit DSU2, and a second bit line BL2, respectively. Here, a read unit of the plurality of bit lines BL is referred to as 1 page. This 1 page can be arbitrarily defined. Read units of the first bit line BL1 and the second bit line BL2 are each referred to as ½ page.

The memory string MS includes a drain-side select transistor STD, a plurality of memory cells MC (memory transistors), and a source-side select transistor STS. The drain-side select transistor STD, the plurality of memory cells MC, and the source-side select transistor STS are connected in series between the bit line BL and the source line SL. Hereinafter, the drain-side select transistor STD and the source-side select transistor STS may be simply referred to as select transistors (STD, STS).

The memory cell MC is a field-effect type transistor. The memory cell MC includes a semiconductor layer, a gate insulating film, and a gate electrode. The semiconductor layer functions as a channel region. The gate insulating film includes an electric charge accumulating film. The memory cell MC has a threshold voltage that changes according to an electric charge amount in the electric charge accumulating film. The memory cell MC stores data of 1 bit or a plurality of bits. Respective word lines WL are connected to the gate electrodes of the plurality of memory cells MC corresponding to one memory string MS. Each of these word lines WL is connected in common to all of the memory strings MS in one memory block BLK.

The select transistors (STD, STS) are field-effect type transistors. The select transistors (STD, STS) include a semiconductor layer, a gate insulating film, and a gate electrode. The semiconductor layer functions as a channel region. The gate insulating film may include an electric charge accumulating layer.

Select gate lines (SGD0, SGS0) are connected to gate electrodes of the select transistors (STD, STS) included in the first divided string unit DSU1, respectively. These select gate lines (SGD0, SGS0) may be referred to as first select gate lines. One drain-side first select gate line SGD0 is connected to drain-side select transistors STD of all the memory strings MS in one first divided string unit DSU1 in common. One source-side first select gate line SGS0 is connected to source-side select transistors STS of all the memory strings MS in one first divided block DBLK1 in common.

Select gate lines (SGD1, SGS1) are connected to gate electrodes of the select transistors (STD, STS) included in the second divided string unit DSU2, respectively. These select gate lines (SGD1, SGS1) may be referred to as second select gate lines. One drain-side second select gate line SGD1 is connected to drain-side select transistors STD of all the memory strings MS in one second divided string unit DSU2 in common. One source-side second select gate line SGS1 is connected to source-side select transistors STS of all the memory strings MS in one second divided block DBLK2 in common.

The drain-side select gate lines SGD0 and SGD1 may be collectively referred to as a drain-side select gate line SGD, the source-side select gate lines SGS0 and SGS1 may be collectively referred to as a source-side select gate line SGS, and the drain-side select gate line SGD and the source-side select gate line SGS may be collectively referred to as a select gate line SG.

### Circuit Configuration of Voltage Generation Circuit VG

As illustrated in FIG. 3, the voltage generation circuit VG generates voltages with predetermined magnitudes in a read operation, a write operation, and an erase operation, and outputs the generated voltages to a voltage select circuit VSEL. For example, the voltage generation circuit VG outputs a read voltage V_{CGR}, a read pass voltage V_{READ}, select gate line voltages V_{SGD} and V_{SGS}, and the like used in the read operation. The voltage generation circuit VG outputs a program voltage V_{PGM}, a write pass voltage V_{PASS}, a verify read voltage V_{CGR}, and the like used in the write operation. The voltage generation circuit VG outputs an erase voltage V_{ERA} and the like used in the erase operation. The voltage generation circuit VG includes, for example, a step-up circuit, such as a charge pump circuit, or a step-down circuit, such as a regulator. Operating voltages output from the voltage generation circuit VG are appropriately adjusted according to a control signal from the sequencer SQC.

The voltage generation circuit VG can generate a plurality of operating voltages applied to the bit line BL, the source line SL, and the select gate lines (SGD, SGS) in the read operation, the write operation, and the erase operation on the memory cell array MCA, and can output the plurality of operating voltages to a plurality of voltage supply lines. These operating voltages are appropriately adjusted according to the control signal from the sequencer SQC.

### Circuit Configuration of Row Decoder RD

For example, as illustrated in FIG. 3, the row decoder RD includes a block decoder BLKD, a voltage select circuit VSEL, and a block select circuit BLKSW.

The block decoder BLKD decodes a block address that is an upper address of a row address RA in the read operation, the write operation, and the like. In the read operation, the write operation, and the like, for example, one signal line BLKSEL corresponding to a block address in the address register ADR (FIG. 1) turns to “H”, and the other signal lines BLKSEL turn to “L”. For example, a predetermined driving voltage having a positive magnitude is applied to the one signal line BLKSEL, and a ground voltage V_{SS} and the like are applied to the other signal lines BLKSEL. These signal lines BLKSEL turn ON any one of the block select circuits BLKSW, and turn OFF the other block select circuits BLKSW. Thus, all of the word lines WL and the select gate lines SG in one memory block BLK corresponding to this block address are electrically conducted with all of wirings CGI. All of the word lines WL and the select gate lines SG in the other memory blocks BLK become a floating state.

The voltage select circuit VSEL decodes a lower address of the row address RA and a divided block selection signal CS1 from the sequencer SQC, and selects a necessary voltage among various kinds of voltages output from the voltage generation circuit VG to output the selected voltage to the wirings CGI. The voltages applied to the drain-side select gate lines SGD00, SGD01, SGD10, and SGD11 of the selected one memory block BLK and the word lines WL and the source-side select gate lines SGS0 and SGS1 of selected one string unit SU in the selected memory block BLK are applied to the wirings CGI. The voltage applied to the word line WL is determined according to the lower address of the row address RA. The respective voltages applied to the drain-side select gate lines SGD00, SGD01, SGD10, and SGD11 and the source-side select gate lines SGS0 and SGS1 are determined according to the divided block selection signal CS1 output from the sequencer SQC.

The block select circuit BLKSW is provided for each memory block BLK. The block select circuit BLKSW includes, for example, a plurality of field-effect type NMOS transistors. These NMOS transistors connect the drain-side select gate lines SGD00, SGD01, SGD10, and SGD11, the word lines WL, and the source-side select gate lines SGS0 and SGS1 of the memory block BLK selected by the block decoder BLKD to the wirings CGI.

### Circuit Configuration of Sense Amplifier Module SAM

For example, as illustrated in FIG. 4, the sense amplifier module SAM detects the ON state/OFF state of the memory cell MC, and acquires data indicating this state of the memory cell MC. Such an operation may be referred to as a sense operation. The sense amplifier module SAM includes a plurality of sense amplifier units SAU. The plurality of sense amplifier units SAU correspond to a plurality of bit lines BL. Each of the plurality of sense amplifier units includes a sense amplifier circuit SA and latch circuits SDL, TDL, ADL, BDL, and CDL. Each of the plurality of sense amplifier units SAU includes a selection circuit SEL. The selection circuit SEL switches connection modes of the bit lines BL1 and BL2 based on a divided block selection signal SC2 from the sequencer SQC. Specifically, the selection circuit SEL selects all the bit lines BL when reading or writing 1 page of data. The selection circuit SEL selects to connect only the first bit line BL1 or the second bit line BL2 when reading or writing ½ page of data.

The sense amplifier module SAM includes a data register DREG. The data register DREG includes, for example, a plurality of latch circuits XDL provided for each sense amplifier unit SAU. The latch circuit XDL temporarily stores read data and write data. The latch circuit XDL is used for data input/output between an external controller and the sense amplifier unit SAU. Each of the latch circuits XDL is connected to the corresponding sense amplifier unit SAU via a bus DBUS. One latch circuit XDL may be connected to a plurality of sense amplifier units SAU.

The sense amplifier circuit SA and latch circuits SDL, ADL, BDL, CDL, and TDL of the sense amplifier unit SAU are connected to a bus LBUS in common. Thus, the latch circuit XDL, the sense amplifier circuit SA, and the latch circuits SDL, ADL, BDL, CDL, and TDL are connected to be able to mutually transmit and receive data.

The sense amplifier circuit SA senses data read by the corresponding bit line BL and determines whether the read data is “0” data or “1” data in the read operation. The sense amplifier circuit SA applies the voltage to the bit line BL based on data stored any of the latch circuits SDL, ADL, BDL, CDL, and TDL in the write operation.

The latch circuits SDL, ADL, BDL, CDL, and TDL temporarily stores the read data and the write data. For example, in the read operation, data may be transferred from the sense amplifier circuit SA to any of the latch circuits SDL, ADL, BDL, CDL, and TDL. In the write operation, data may be transferred from the latch circuit XDL to any of the latch circuits SDL, ADL, BDL, CDL, and TDL.

The configuration of the sense amplifier unit SAU is not limited to this, and can be variously changed. For example, the number of the latch circuits included in the sense amplifier unit SAU may be designed based on the number of bits of the data that can be stored in one memory cell MC.

### Circuit Configuration of Cache Memory CM

As illustrated in FIG. 1, the cache memory CM includes a plurality of latch circuits. The plurality of latch circuits are connected to the latch circuits in the sense amplifier module SAM via the bus DBUS. Data DAT included in these plurality of latch circuits are sequentially transferred to the sense amplifier module SAM or the input/output control circuit I/O.

The cache memory CM is connected to a decode circuit and a switch circuit (not illustrated). The decode circuit decodes a column address CA latched in the address register ADR. The switch circuit electrically conducts the latch circuit corresponding to the column address CA and a bus BUS (FIG. 1) according to the output signal from the decode circuit.

### Circuit Configuration of Sequencer SQC

As illustrated in FIG. 1, the sequencer SQC outputs an internal control signal to the row decoder RD, the sense amplifier module SAM, and the voltage generation circuit VG in response to command data D_{CMD} latched in the command register CMR. The sequencer SQC outputs status data D_{ST} indicating its own state to the status register STR as appropriate.

The sequencer SQC generates a ready/busy signal and outputs the ready/busy signal to a terminal RY//BY. In a period when the terminal RY//BY is in an “L” state (a busy period), access to the memory die MD is basically inhibited. In a period when the terminal RY//BY is in an “H” state (a ready period), access to the memory die MD is permitted.

### Circuit Configuration of Input/output Control Circuit I/O

The input/output control circuit I/O includes data signal input/output terminals DQ0 to DQ7, toggle signal input/output terminals DQS and /QS, a plurality of input circuits, a plurality of output circuits, a shift register, and a buffer circuit. The plurality of input circuits, the plurality of output circuits, the shift register, and the buffer circuit are connected to respective terminals to which a power supply voltage V_{CCQ} and the ground voltage V_{SS} is applied.

The data input via the data signal input/output terminals DQ0 to DQ7 is output to the cache memory CM, the address register ADR, or the command register CMR from the buffer circuit in response to the internal control signal from the logic circuit CTR. The data output via the data signal input/output terminals DQ0 to DQ7 is input to the buffer circuit from the cache memory CM or the status register STR in response to the internal control signal from the logic circuit CTR.

The plurality of input circuits include, for example, comparators connected to any of the data signal input/output terminals DQ0 to DQ7 or both of the toggle signal input/output terminals DQS and /QS. The plurality of output circuits include, for example, Off Chip Drivers (OCD) circuit connected to any of the data signal input/output terminals DQ0 to DQ7 or either of the toggle signal input/output terminals DQS and /QS.

### Circuit Configuration of Logic Circuit CTR

The logic circuit CTR (FIG. 1) receives external control signals from the controller die CD via external control terminals /En, CLE, ALE, /WE, RE, and /RE and outputs the internal control signals to the input/output control circuit I/O according to the external control signals.

### Structure of Memory Die MD

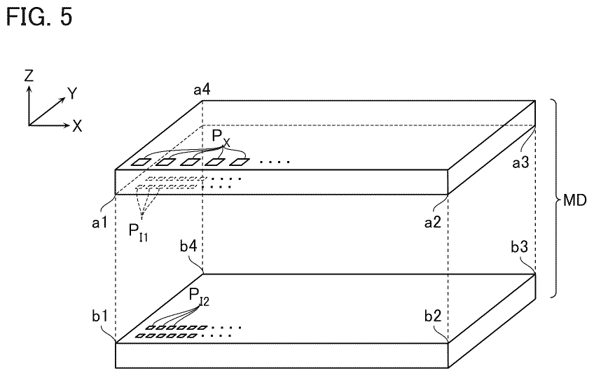

FIG. 5 is a schematic exploded perspective view illustrating an exemplary configuration of the semiconductor memory device according to the first embodiment. As illustrated in FIG. 5, the memory die MD includes a chip C_{M} on a memory cell array MCA side and a chip C_{P} on a peripheral circuit PC side.

On an upper surface of the chip C_{M}, a plurality of external pad electrodes P_{X} enabled to be connected to bonding wires, which are not illustrated, are provided. On a lower surface of the chip C_{M}, a plurality of bonding electrodes P_{I1} are provided. On an upper surface of the chip C_{P}, a plurality of bonding electrodes P_{I2} are provided. In the following description, a surface of the chip C_{M} on which the plurality of bonding electrodes P_{I1} are formed is referred to as a front surface, and a surface of the chip C_{M} on which the plurality of external pad electrodes P_{X} are formed is referred to as a back surface. In the case of the chip C_{P}, a surface on which the plurality of bonding electrodes P_{I2} are formed is referred to as a front surface, and a surface opposite to the front surface is referred to as a back surface.

The chip C_{M} and the chip C_{P} are arranged such that the front surface of the chip C_{M} faces the front surface of the chip C_{P}. The plurality of bonding electrodes P_{I1} are provided in correspondence with the plurality of bonding electrodes P_{I2}, and are arranged in positions where the plurality of bonding electrodes P_{I1} are allowed to be bonded to the plurality of bonding electrodes P_{I2}. The bonding electrode P_{I1} and the bonding electrode P_{I2} function as bonding electrodes for bonding the chip C_{M} and the chip C_{P} and allowing electrical conduction.

In the example in FIG. 5, corner portions a1, a2, a3, and a4 of the chip C_{M} correspond to corner portions b1, b2, b3, and b4 of the chip C_{P}, respectively.

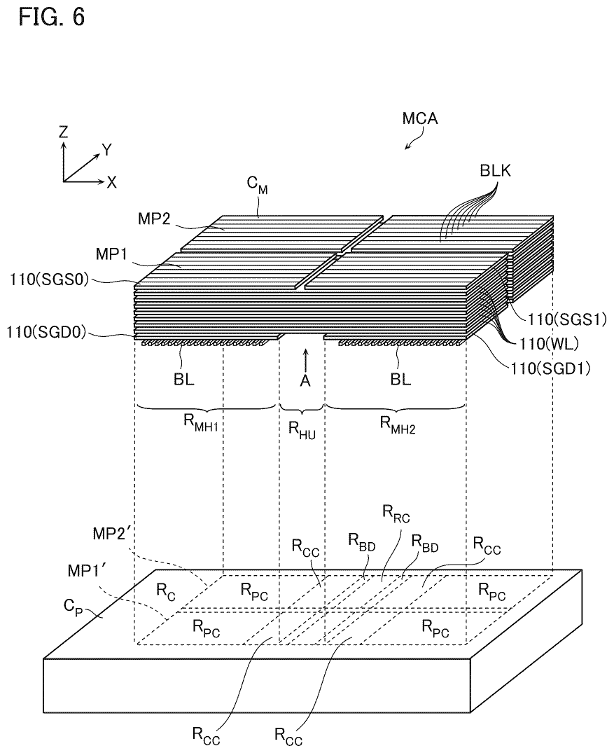

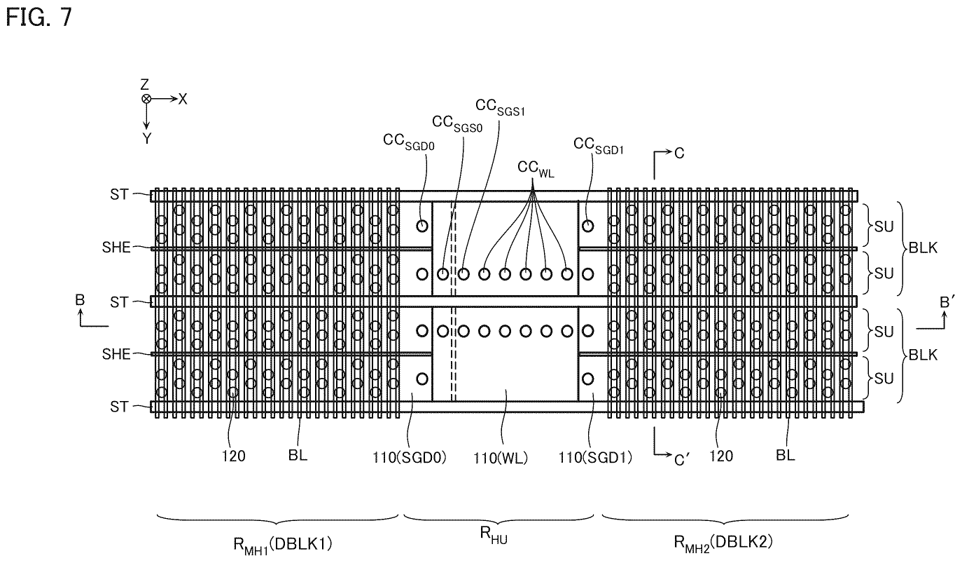

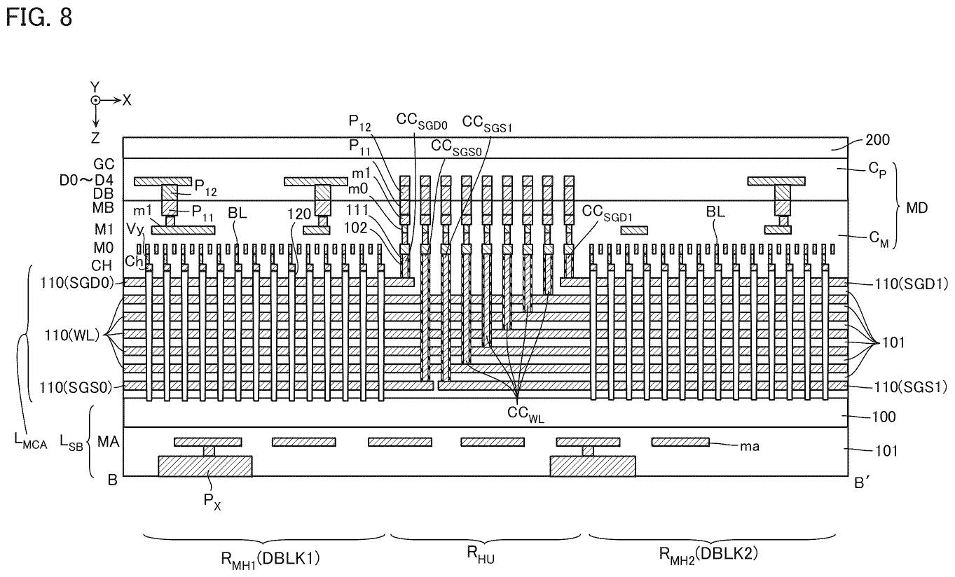

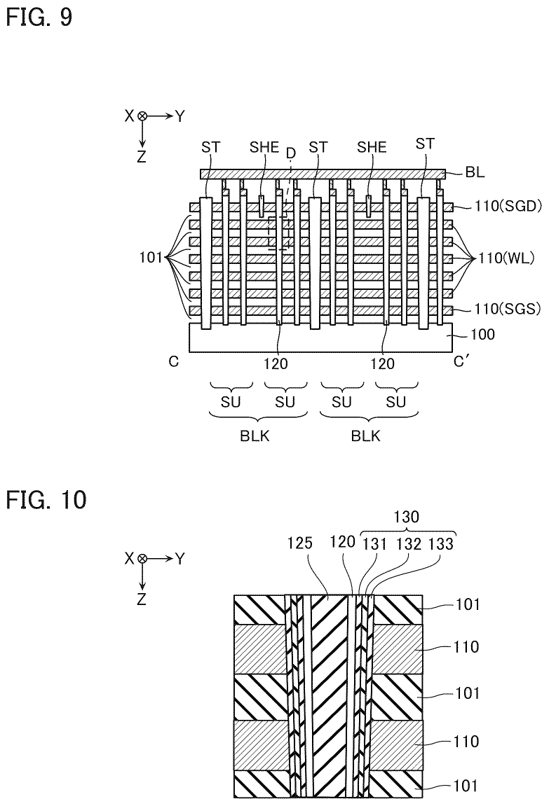

FIG. 6 is a schematic perspective view of the chip C_{M} and the chip C_{P}. FIG. 6 omits a part of the configuration such as the bonding electrodes P_{I1}. FIG. 7 is a schematic bottom view illustrating a configuration of a part of the chip C_{M} when viewed in a direction of an arrow A in FIG. 6. FIG. 8 is a schematic cross-sectional view of a part of the chip C_{M} taken along line B-B′ and viewed in an arrow direction in FIG. 7. FIG. 9 is a schematic cross-sectional view of a part of the chip C_{M} taken along line C-C′ and viewed in an arrow direction in FIG. 7. FIG. 10 is a schematic cross-sectional view illustrating an enlarged part D in FIG. 9.

In the example of FIG. 6, the chip C_{M} includes two memory planes MP1 and MP2 arranged in the Y-direction. The two memory planes MP1 and MP2 may be each simply referred to as a memory plane MP. Each of these two memory planes MP1 and MP2 includes a plurality of memory blocks BLK arranged in the Y-direction. In the example of FIG. 6, each of these two memory planes MP1 and MP2 includes a first memory region R_{MH1} and a second memory region R_{MH2} provided on both sides in the X-direction, and a hook-up region R_{HU} provided between these first memory region R_{MH1} and second memory region R_{MH2}. In the example of FIG. 6, peripheral circuits provided around the memory cell array MCA are omitted.

In the illustrated example, the hook-up region R_{HU} is provided in the center portion in the X-direction of the memory plane MP. However, this configuration is only an example, and the specific configuration can be changed as appropriate. For example, the hook-up region R_{HU} may be provided not at the center portion in the X-direction but at both end portions in the X-direction of the memory plane MP.

### Structure of Chip C_{M}

Next, the structure of the chip C_{M} is described. In the following description, for convenience, a chip C_{P} side is referred to as an upper side, and a chip C_{M} side is referred to as a lower side. For example, as illustrated in FIG. 8, the chip C_{M} includes a substrate layer L_{SB}, a memory cell array layer L_{MCA} provided above the substrate layer L_{SB}, a via-contact electrode layer CH provided above the memory cell array layer L_{MCA}, a plurality of wiring layers M0 and M1 provided above the via-contact electrode layer CH, and a chip bonding electrode layer MB provided above the wiring layers M0 and M1.

### Structure of Substrate Layer L_{SB} of Chip C_{M}

For example, as illustrated in FIG. 8, the substrate layer L_{SB} includes a conductive layer 100 provided on a lower surface of the memory cell array layer L_{MCA}, an insulating layer 101 provided on a lower surface of the conductive layer 100, a back side wiring layer MA provided at the insulating layer 101, and an external pad electrode P_{X} connected to a lower surface of the back side wiring layer MA.

For example, the conductive layer 100 may include a semiconductor layer of silicon (Si) or the like doped with N-type impurities, such as phosphorus (P), or P-type impurities, such as boron (B), may contain metal, such as tungsten (W), and may contain silicide, such as tungsten silicide (WSi).

The conductive layer 100 functions as a part of the source line SL (FIG. 1). Two conductive layers 100 are provided corresponding to the two memory planes MP1 and MP2 (FIG. 6). The insulating layer 101 contains, for example, silicon oxide (SiO₂).

The back side wiring layer MA includes a plurality of wirings ma. These plurality of wirings ma may contain, for example, aluminum (Al). A part of the plurality of wirings ma functions as a part of the source lines SL (FIG. 2).

### Structure of Memory Cell Array Layer L_{MCA} of Chip C_{M} in Memory Region R_{MH}

As described with reference to FIG. 6, the memory cell array layer L_{MCA} includes a plurality of memory blocks BLK arranged in the Y-direction. As illustrated in FIG. 7 and FIG. 9, between two memory blocks BLK adjacent in the Y-direction, an inter-block insulating layer ST of silicon oxide (SiO₂) or the like is provided. The inter-block insulating layer ST may be provided with a conductive layer including, for example, an insulating film of silicon oxide (SiO₂) or the like, a barrier conductive film of titanium nitride (TiN) or the like, and a metal film of tungsten (W) or the like.

For example, as illustrated in FIG. 9, the memory block BLK includes a plurality of conductive layers 110 arranged in the Z-direction and a plurality of semiconductor layers 120 extending in the Z-direction. As illustrated in FIG. 10, which illustrates an enlarged part D in FIG. 9, respective gate insulating films 130 are provided between the plurality of conductive layers 110 and the plurality of semiconductor layers 120.

The conductive layer 110 has an approximately plate shape extending in the X-direction. The conductive layer 110 may include, for example, a stacked film of a barrier conductive film of titanium nitride (TiN) or the like and a metal film of tungsten (W), molybdenum (Mo) or the like. The conductive layer 110 may contain, for example, polycrystalline silicon containing impurities, such as phosphorus (P) or boron (B). Between the plurality of conductive layers 110 arranged in the Z-direction, insulating layers 101 of silicon oxide (SiO₂) or the like are provided.

Among the plurality of conductive layers 110, one or a plurality of conductive layers 110 (SGS) positioned at lowermost layers function as gate electrodes of the source-side select transistors STS (FIG. 2) and the source-side select gate line SGS. These one or a plurality of conductive layers 110 (SGS) are electrically independent for each memory block BLK.

A plurality of conductive layers 110 (WL) positioned above these conductive layers 110 (SGS) function as gate electrodes of the memory cells MC (FIG. 2) and the word lines WL. These plurality of conductive layers 110 (WL) are each electrically independent for each memory block BLK.

One or a plurality of conductive layers 110 (SGD) positioned above these conductive layers 110 (WL) function as gate electrodes of the drain-side select transistors STD and the drain-side select gate line SGD. For example, as illustrated in FIG. 9, these plurality of conductive layers 110 (SGD) have a width in the Y-direction smaller than a width in the Y-direction of the conductive layers 110 (WL) that function as the word lines WL. Between two conductive layers 110 (SGD) adjacent in the Y-direction, an inter-string unit insulating layer SHE of silicon oxide (SiO₂) or the like is provided.

For example, as illustrated in FIG. 7, the semiconductor layers 120 are arranged in the X-direction and the Y-direction in a predetermined pattern. The respective semiconductor layers 120 function as channel regions of the plurality of memory cells MC and the select transistors (STD, STS) included in one memory string MS (FIG. 2). The semiconductor layer 120 contains, for example, polycrystalline silicon (Si). The semiconductor layer 120 has an approximately cylindrical shape, and as illustrated in FIG. 10, includes an insulating layer 125 of silicon oxide or the like at the center portion of the semiconductor layer 120. Each of the semiconductor layers 120 has an outer peripheral surface surrounded by the plurality of conductive layers 110 and facing these plurality of conductive layers 110.

At a lower end of the semiconductor layer 120, an impurity region (not illustrated) is provided. This impurity region is connected to the conductive layer 100. This impurity region contains, for example, N-type impurities, such as phosphorus (P), or P-type impurities, such as boron (B).

At an upper end of the semiconductor layer 120, an impurity region (not illustrated) is provided. As illustrated in FIG. 8, this impurity region is connected to the bit line BL via a via-contact electrode Ch and a via-contact electrode Vy. This impurity region contains, for example, N-type impurities, such as phosphorus (P).

For example, as illustrated in FIG. 10, the gate insulating film 130 has an approximately cylindrical shape that covers the outer peripheral surface of the semiconductor layer 120. The gate insulating film 130 includes a tunnel insulating film 131, an electric charge accumulating film 132, and a block insulating film 133, which are stacked between the semiconductor layer 120 and the conductive layers 110. The tunnel insulating film 131 and the block insulating film 133 contain, for example, silicon oxide (SiO₂), silicon oxynitride (SiON), and the like. The electric charge accumulating film 132 includes, for example, a film that can accumulate electric charges of silicon nitride (SiN) or the like. The tunnel insulating film 131, the electric charge accumulating film 132, and the block insulating film 133 have an approximately cylindrical shape, and extend in the Z-direction along the outer peripheral surface of the semiconductor layer 120 excluding a contact portion between the semiconductor layer 120 and the conductive layer 100.

FIG. 10 illustrates an example in which the gate insulating film 130 includes the electric charge accumulating film 132 of silicon nitride or the like. However, the gate insulating film 130 may, for example, include a floating gate of polycrystalline silicon including N-type or P-type impurities, or the like.

### Structure of Memory Cell Array Layer L_{MCA} of Chip C_{M} in Hook-Up Region R_{HU}

As illustrated in FIG. 8, in the hook-up region R_{HU}, the uppermost conductive layer 110 (SGD) that functions as the drain-side select gate line SGD is divided in the X-direction. That is, the conductive layer 110 (SGD) includes a conductive layer 110 (SGD0) (first divided layer) that functions as the drain-side first select gate line SGD0 of the first divided block DBLK1 positioned in the first memory region R_{MH1}, and a conductive layer 110 (SGD1) (second divided layer) that functions as the drain-side second select gate line SGD1 of the second divided block DBLK2 positioned in the second memory region R_{MH2}.

In the hook-up region R_{HU}, the lowermost conductive layer 110 (SGS) that functions as the source-side select gate line SGS is divided in the X-direction. That is, the conductive layer 110 (SGS) includes a conductive layer 110 (SGS0) (third divided layer) that functions as the source-side first select gate line SGS0 of the first divided block DBLK1 positioned in the first memory region R_{MH1}, and a conductive layer 110 (SGS1) (fourth divided layer) that functions as the source-side second select gate line SGS1 of the second divided block DBLK2 positioned in the second memory region R_{MH2}.

In the hook-up region R_{HU}, a plurality of via-contact electrodes CC_{WL}, CC_{SGD0}, CC_{SGD1}, CC_{SGS0}, and CC_{SGS1} are provided. These plurality of via-contact electrodes CC_{WL}, CC_{SGD0}, CC_{SGD1}, CC_{SGS0}, and CC_{SGS1} extend in the Z-direction and have lower ends connected to the conductive layers 110 (WL), 110 (SGD0), 110 (SGD1), 110 (SGS0), and 110 (SGS1), respectively. Hereinafter, the plurality of via-contact electrodes CC_{WL}, CC_{SGD0}, CC_{SGD1}, CC_{SGS0}, and CC_{SGS1} may be collectively referred to as a via-contact electrode CC. The via-contact electrode CC has an upper end electrically connected to a bonding electrode P₁₂ of the chip C_{P} via wirings m0, m1 and a bonding electrode P₁₁.

The via-contact electrode CC includes a columnar conductive layer 111 extending in the Z-direction and an insulating layer 102 that covers an outer periphery of the conductive layer 111. The insulating layer 102 insulates the conductive layer 111 from the conductive layers 110 other than the conductive layer 110 to be connected. The conductive layer 111 may include, for example, a stacked film of a barrier conductive film of titanium nitride (TiN) or the like and a metal film of tungsten (W) or the like. The insulating layer 102 may contain silicon oxide (SiO₂) or the like.

### Structure of Via-Contact Electrode Layer CH

The plurality of via-contact electrodes Ch included in the via-contact electrode layer CH are electrically connected to, for example, at least one of configurations in the memory cell array layer L_{MCA} and configurations in the chip C_{P}.

The via-contact electrode layer CH includes a plurality of via-contact electrodes Ch as a plurality of wirings. These plurality of via-contact electrodes Ch may include, for example, a stacked film of a barrier conductive film of titanium nitride (TiN) or the like and a metal film of tungsten (W) or the like. The via-contact electrodes Ch are provided corresponding to the plurality of semiconductor layers 120, and connected to lower ends of the plurality of semiconductor layers 120.

### Structure of Wiring Layers M0 and M1 of Chip C_{M}

A plurality of wirings included in the wiring layers M0 and M1 are electrically connected to, for example, at least one of configurations in the memory cell array layer L_{MCA} and configurations in the chip C_{P}.

The wiring layer M0 includes a plurality of wirings m0. These plurality of wirings m0 may include, for example, a stacked film of a barrier conductive film, which contains titanium nitride (TiN), tantalum nitride (TaN), a stacked film of tantalum nitride (TaN) and tantalum (Ta), or the like, and a metal film of copper (Cu) or the like. A part of the plurality of wirings m0 functions as the bit lines BL. For example, as illustrated in FIG. 7, the bit lines BL are arranged in the X-direction and extend in the Y-direction.

For example, as illustrated in FIG. 8, the wiring layer M1 includes a plurality of wirings m1. These plurality of wirings m1 may include, for example, a stacked film of a barrier conductive film of titanium nitride (TiN) or the like and a metal film of tungsten (W) or the like.

### Structure of Chip C_{P}

For example, as illustrated in FIG. 6, the chip C_{P} includes regions MP1′ and MP2′ overlapping with the two memory planes MP1 and MP2 arranged in the Y-direction. In each of the center portions in the X-direction of these two regions MP1′ and MP2′, a row control circuit region R_{RC} is provided. Two block decoder regions R_{BD} arranged in the X-direction are provided on both sides in the X-direction of the row control circuit region R_{RC}. At outsides of these block decoder regions R_{BD}, respective column control circuit regions R_{CC} are provided. At outsides of these column control circuit regions R_{CC}, peripheral circuit regions R_{PC} are provided. Also in the other region, a circuit region R_{C} is provided.

In the row control circuit region R_{RC}, a plurality of block select circuits BLKSW described with reference to FIG. 3 are provided. That is, in the row control circuit region R_{RC}, a plurality of NMOS transistors constituting a plurality of block select circuits BLKSW are provided. In the block decoder region R_{BD}, the block decoder BLKD described with reference to FIG. 3 is provided. In the column control circuit region R_{CC}, the sense amplifier module SAM described with reference to FIG. 4 is provided. In the circuit region R_{C}, an input/output circuit (not illustrated) is provided. This input/output circuit is connected to the external pad electrode P_{X} via the via-contact electrode CC and the like described with reference to FIG. 8.

For example, as illustrated in FIG. 8, the chip C_{P} includes a semiconductor substrate 200, an electrode layer GC provided above the semiconductor substrate 200, wiring layers D0, D1, D2, D3, and D4 provided above the electrode layer GC, and a chip bonding electrode layer DB provided above the wiring layer D0, D1, D2, D3, and D4. The semiconductor substrate 200 contains, for example, P-type silicon (Si) containing P-type impurities, such as boron (B). On a surface of the semiconductor substrate 200, for example, a plurality of transistors constituting the peripheral circuit PC, a plurality of resistors, a capacitor, and the like are provided. At the chip bonding electrode layer DB, the bonding electrodes P₁₂ are provided.

### Operations

Next, operations of the memory die MD according to the first embodiment is described.

### Read Operation

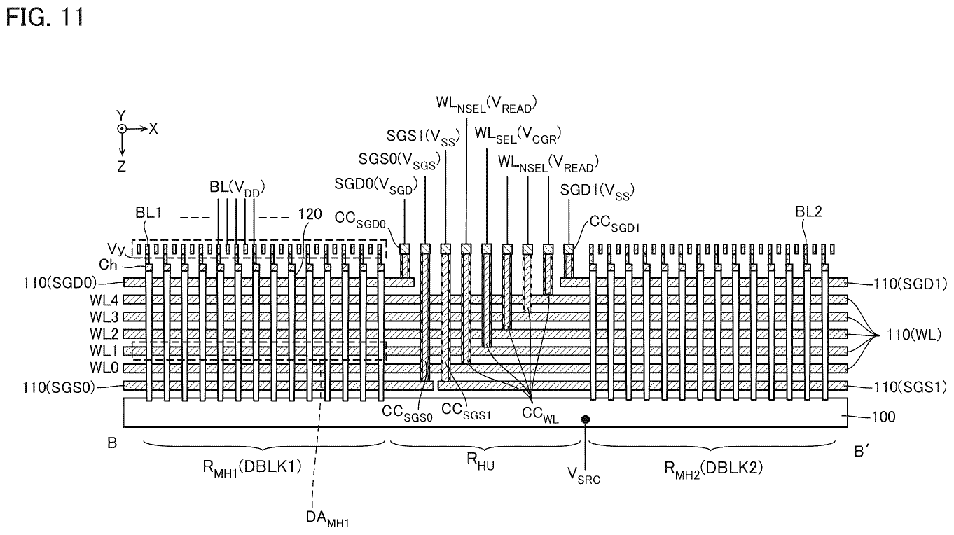

FIG. 11 illustrates a main part of FIG. 8, and is a diagram schematically illustrating voltages applied to respective portions in a read operation of the memory die MD according to the first embodiment. To simplify the explanation, details of the voltage application timing are omitted.

First, a case of reading ½ page of data DA_{MH1} stored in the memory cell MC connected to a word line WL1 of the first divided block DBLK1 from the first bit line BL1 is described.

When a command to read the data from the memory cell MC connected to the word line WL1 of the first divided block DBLK1 is input, the sequencer SQC (FIG. 1) sets the divided block selection signals SC1 and SC2 to a signal level for selecting the first divided block DBLK1. A voltage V_{SRC} is applied to the conductive layer 100 that functions as the source line. The voltage V_{SRC} is greater than the ground voltage V_{SS}, but approximately equal to the ground voltage V_{SS}. A voltage V_{DD} is charged to the first bit line BL1 and the second bit line BL2 via the sense amplifier module SAM.

The voltage V_{SGD} is applied to the drain-side first select gate line SGD0 and the voltage V_{SGS} is applied to the source-side first select gate line SGS0 in the selected first divided block DBLK1. The voltage V_{SGD} is a gate voltage that is greater than the voltage V_{SS} and turns ON the drain-side select transistor STD. The voltage V_{SGS} is a gate voltage that is greater than the voltage V_{SS} and turns ON the source-side select transistor STS. The voltage V_{SGD} and the voltage V_{SGS} may be same, or may be different.

The voltage V_{CGR} in a threshold level of binary or more is applied in phases to a selected word line WL_{SEL} connected to the memory cell MC from which the data is read. On the other hand, the voltage V_{READ} is applied to unselected word lines WL_{NSEL} connected to the memory cells MC from which the data is not read. The voltage V_{READ} is a voltage that is greater than the voltage V_{CGR} and constantly turns ON the memory cell MC regardless of the value of the data stored in the memory cell MC.

When the above-described respective voltages are applied to the word lines WL and the select gate lines SGD0 and SGS0, the select transistors STD and STS connected to the selected string unit SU turn ON. All the memory cells MC connected to the unselected word lines WL_{NSEL} turn ON. Among the memory cells MC connected to the selected word line WL_{SEL}, the selected memory cells MC in the threshold level greater than that of the voltage V_{CGR} turn OFF, therefore, the voltage of the first bit line BL1 keeps the voltage V_{DD}. Meanwhile, among the memory cells MC connected to the selected word line WL_{SEL}, the selected memory cells MC in the threshold level smaller than that of the voltage V_{CGR} turn ON, therefore, the voltage V_{DD} of the first bit line BL1 is discharged to a conductive layer 100 side via the drain-side select transistor STD, the memory cell MC, and the source-side select transistor STS, and drops to the voltage V_{SS}. By detecting these voltage states of the first bit line BL1 with the sense amplifier module SAM, ½ page of read data DA_{MH1} can be read into the latch circuit XDL.

On the other hand, in an unselected second divided block DBLK2 side, the sense amplifier module SAM is not connected to the second bit line BL2. The voltage V_{SS} (or a voltage greater than the voltage V_{SS} and close to the voltage V_{SS}) is applied to the drain-side second select gate line SGD1 and the source-side second select gate line SGS1 of the unselected second divided block DBLK2. The voltage V_{SS} is a gate voltage that does not turn ON either the drain-side select transistor STD or the source-side select transistor STS. Thus, the second divided block DBLK2 becomes a floating state. Therefore, charging to the conductive layer 110 positioned in the second memory region R_{MH2} is not performed.

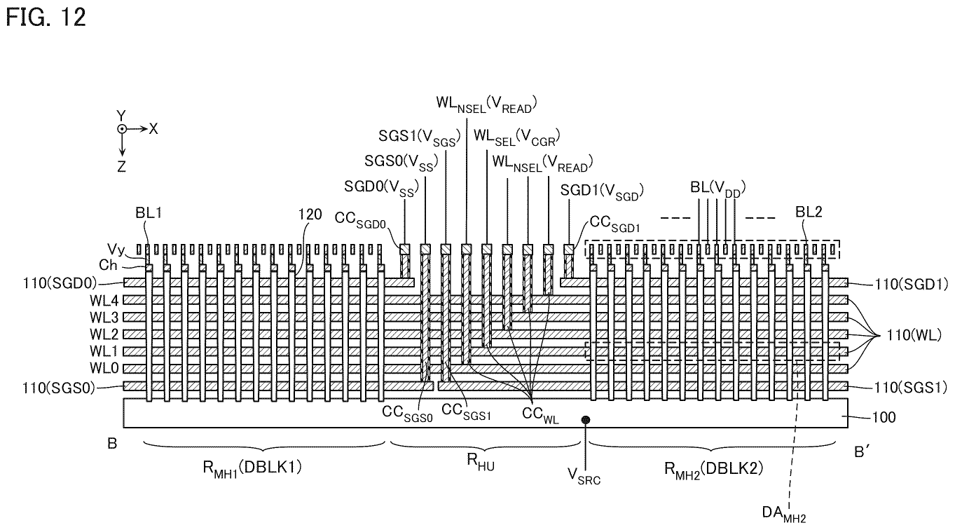

FIG. 12 is a diagram for describing another read operation. Here, a case of reading ½ page of data DA_{MH2} stored in the memory cell MC connected to a word line WL1 of the second divided block DBLK2 from the second bit line BL2 is described. The explanation of parts overlapping with the explanation of FIG. 11 is omitted.

When a command to read the data from the memory cell MC connected to a word line WL2 of the second divided block DBLK2 is input, the sequencer SQC (FIG. 1) sets the divided block selection signals SC1 and SC2 to a signal level for selecting the second divided block DBLK2. A voltage V_{SRC} is applied to the conductive layer 100 that functions as the source line. A voltage V_{DD} is charged to the first bit line BL1 and the second bit line BL2 via the sense amplifier module SAM.

The voltage V_{SGD} is applied to the drain-side second select gate line SGD1 and the voltage V_{SGS} is applied to the source-side second select gate line SGS1 in the selected second divided block DBLK2.

The voltage V_{CGR} in a threshold level of binary or more is applied in phases to a selected word line WL_{SEL} connected to the memory cell MC from which the data is read. On the other hand, the voltage V_{READ} is applied to unselected word lines WL_{NSEL} connected to the memory cells MC from which the data is not read.

The operation in the second divided block DBLK2 when the above-described respective voltages are applied to the word lines WL and the select gate lines SGD1 and SGS1 is similar to the operation in the first divided block DBLK1 in FIG. 11. Thus, ½ page of read data DA_{MH2} can be read into the latch circuit XDL.

On the other hand, in an unselected first divided block DBLK1 side, the sense amplifier module SAM is not connected to the first bit line BL1. The voltage V_{SS} (or a voltage greater than the voltage V_{SS} and close to the voltage V_{SS}) is applied to the drain-side first select gate line SGD0 and the source-side first select gate line SGS0 of the unselected first divided block DBLK1. Thus, the first divided block DBLK1 becomes a floating state. Therefore, charging to the conductive layer 110 positioned in the first memory region R_{MH1} is not performed.

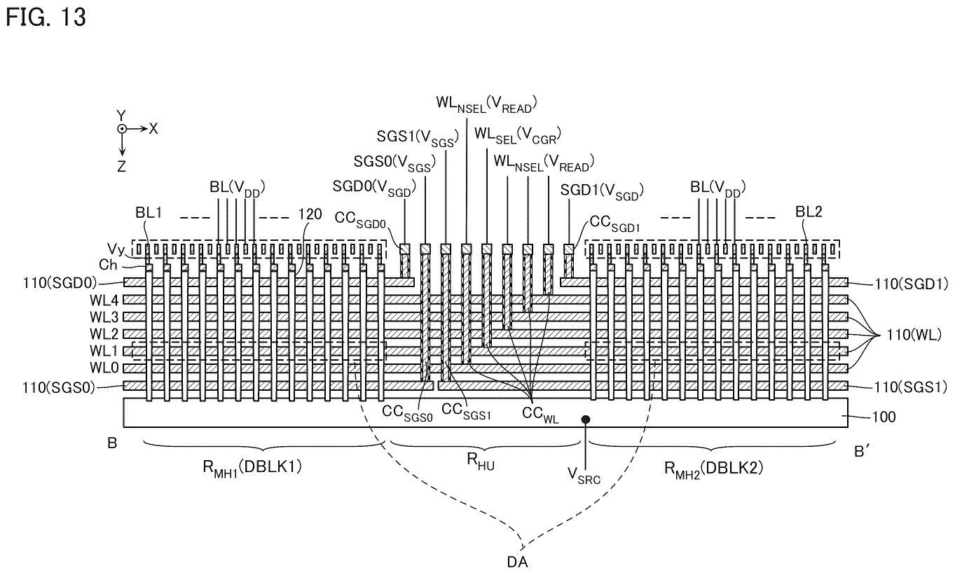

FIG. 13 is a diagram for describing still another read operation. Here, a case of reading 1 page of data DA stored in the memory cell MC connected to the word line WL1 in the first divided block DBLK1 and the second divided block DBLK2 from the first bit line BL1 and the second bit line BL2 is described. The explanation of parts overlapping with the explanation of FIG. 11 and FIG. 12 is omitted.

When an ordinary command to read 1 page of data is input, the sequencer SQC (FIG. 1) sets the divided block selection signals SC1 and SC2 to a signal level for selecting the first divided block DBLK1 and the second divided block DBLK2. A voltage V_{SRC} is applied to the conductive layer 100 that functions as the source line. A voltage V_{DD} is charged to the first bit line BL1 and the second bit line BL2 via the sense amplifier module SAM.

The voltage V_{SGD} is applied to the drain-side first select gate line SGD0 of the first divided block DBLK1 and the drain-side second select gate line SGD1 of the second divided block DBLK2, and the voltage V_{SGS} is applied to the source-side first select gate line SGS0 and the source-side second select gate line SGS1.

The voltage V_{CGR} in a threshold level of binary or more is applied in phases to a selected word line WL_{SEL} connected to the memory cell MC from which the data is read. On the other hand, the voltage V_{READ} is applied to unselected word lines WL_{NSEL} connected to the memory cells MC from which the data is not read.

Thus, ½ page of data DA_{MH1} and DA_{MH2} can be read from the first divided block DBLK1 and the second divided block DBLK2, respectively.

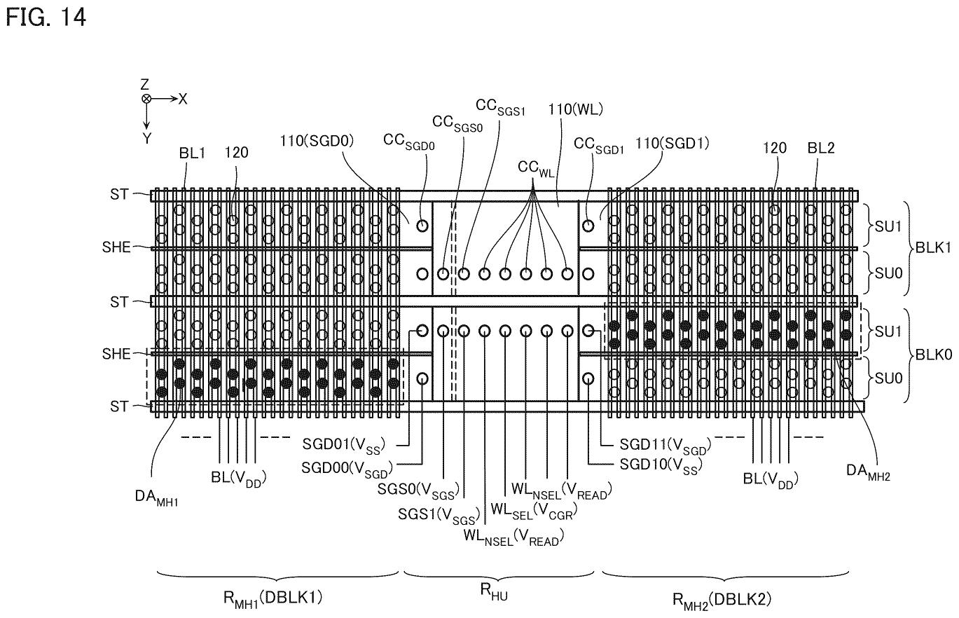

FIG. 14 is a diagram for describing still another read operation. Here, an example of simultaneously reading ½ page of data DA, 1 page of data DA in total, from the different string units SU0 and SU1 in the same memory block BLK0 is described. FIG. 14 corresponds to FIG. 7.

The voltages applied to the word lines WL and the source-side select gate lines SGS0 and SGS1 are same as the voltages described in FIG. 13. In this example, in the first divided block DBLK1, the string unit SU0 is selected. In the second divided block DBLK2, the string unit SU1 is selected.

The voltage V_{SGD} is applied to the drain-side first select gate line SGD00 connected to the string unit SU0, and the voltage V_{SS} is applied to the drain-side first select gate line SGD01 connected to the string unit SU1 in the first divided block DBLK1.

On the other hand, the voltage V_{SS} is applied to the drain-side second select gate line SGD10 connected to the string unit SU0, and the voltage V_{SGD} is applied to the drain-side second select gate line SGD11 connected to the string unit SU1 in the second divided block DBLK2.

Thus, in the first divided block DBLK1, ½ page of data DA_{MH1} is read from the string unit SU0, and in the second divided block DBLK2, ½ page of data DA_{MH2} is read from the string unit SU1.

### Write Operation

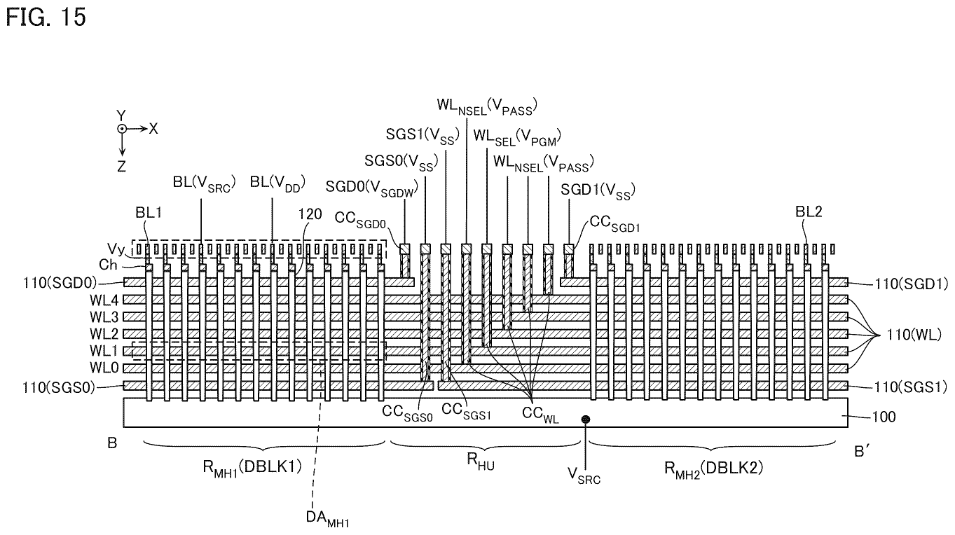

FIG. 15 illustrates the main part of FIG. 8, and is a diagram schematically illustrating voltages applied to respective portions in a write operation of the memory die MD according to the first embodiment. To simplify the explanation, details of the voltage application timing are omitted.

Here, a case of writing ½ page of the data DA_{MH1} on the memory cell MC connected to the word line WL1 of the first divided block DBLK1 via the first bit line BL1 is described.

When a command to write the data on the memory cell MC connected to the word line WL1 of the first divided block DBLK1 is input, the sequencer SQC (FIG. 1) sets the divided block selection signals SC1 and SC2 to a signal level for selecting the first divided block DBLK1. The voltage V_{SRC} is applied to the conductive layer 100 that functions as the source line. The sense amplifier module SAM connects the first bit line BL1, and the voltage V_{DD} or V_{SRC} corresponding to the write data is applied to the first bit line BL1 via the sense amplifier module SAM. That is, the voltage V_{SRC} is applied to the first bit line BL1 connected to the memory cell MC in which the threshold is increased, and the voltage V_{DD} is applied to the first bit line BL1 connected to the memory cell MC in which the threshold is not varied.

A voltage V_{SGDW} is applied to the drain-side first select gate line SGD0 and the voltage V_{SS} is applied to the source-side first select gate line SGS0 in the selected first divided block DBLK1. The voltage V_{SGDW} is greater than the voltages V_{SRC} and V_{DD}. The voltage V_{SGDW} is a voltage that turns ON the drain-side select transistor STD connected to the first bit line BL1 to which the voltage V_{SRC} is applied and does not turn ON the drain-side select transistor STD connected to the first bit line BL1 to which the voltage V_{DD} is applied.

The program voltage V_{PGM} is applied to the selected word line WL_{SEL} connected to the memory cell MC on which the data is written, and a write pass voltage V_{PASS} is applied to the unselected word line WL_{NSEL} connected to the memory cell MC on which the data is not written. The program voltage V_{PGM} is greater than the write pass voltage V_{PASS}. The write pass voltage V_{PASS} is a voltage that turns ON the memory cell MC.

When the above-described respective voltages are applied to the word lines WL and the select gate lines SGD0 and SGS0, the source-side select transistor STS turns OFF, and therefore, the memory cell MC is disconnected from the conductive layer 100.

When the voltage applied to the first bit line BL1 is the voltage V_{SRC}, the drain-side select transistor STD connected to this first bit line BL1 turns ON, and the voltage V_{SRC} is transferred to the channel formed at the memory string MS. Meanwhile, when the voltage applied to the first bit line BL1 is the voltage V_{DD}, the drain-side select transistor STD connected to this first bit line BL1 turns OFF, and the channel formed at the memory string MS becomes a floating state.

When the program voltage V_{PGM} is applied to the selected word line WL_{SEL} in this state, in the memory cell MC having the channel to which the voltage V_{SRC} has been transferred, the electrons move from the channel to the electric charge accumulating film 132 (FIG. 10) via the tunnel insulating film 131 (FIG. 10), and the threshold voltage of the memory cell MC increases. Since a write verify operation is similar to the read operation illustrated in FIG. 11, the explanation is omitted here. Meanwhile, in the memory cell MC having the channel to which the voltage V_{SRD} has not been transferred, the channel is boosted and the electrons do not move. Thus, ½ page of the data DA_{MH1} stored in the latch circuit XDL can be written on the memory cell MC of the first divided block DBLK1.

On the other hand, in the unselected second divided block DBLK2 side, the voltage V_{SS} (or a voltage greater than the voltage V_{SS} and close to the voltage V_{SS}) is applied to the drain-side second select gate line SGD1 and the source-side second select gate line SGS1. Therefore, the second divided block DBLK2 becomes a floating state, and the write operation is not performed.

### Erase Operation

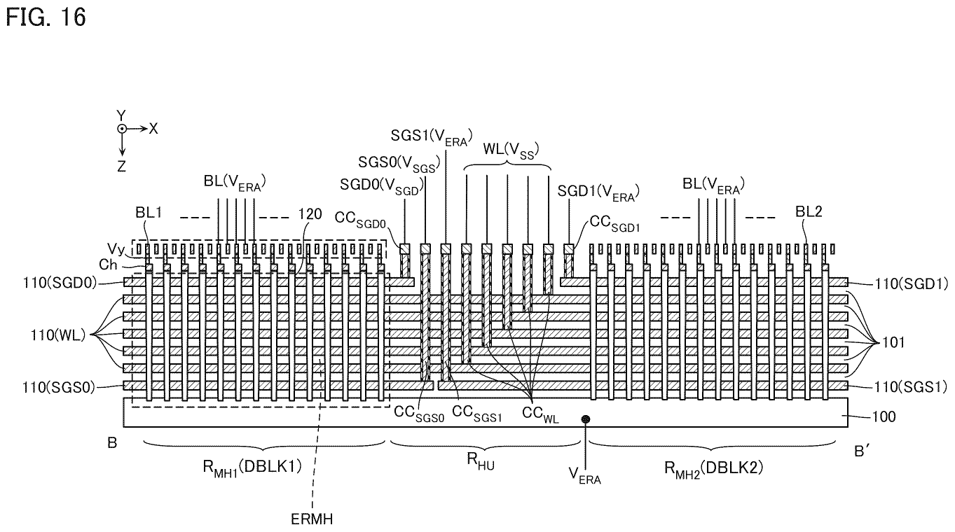

FIG. 16 illustrates the main part of FIG. 8, and is a diagram schematically illustrating voltages applied to respective portions in an erase operation of the memory die MD according to the first embodiment. To simplify the explanation, details of the voltage application timing are omitted.

Here, a case where the first divided block DBLK1 is assumed to be an erase target memory portion ERMH is described.

When a command to erase the first divided block DBLK1 is input, the sequencer SQC (FIG. 1) sets the divided block selection signals SC1 and SC2 to a signal level for selecting the first divided block DBLK1. The erase voltage V_{ERA} is applied to the conductive layer 100 that functions as the source line. The erase voltage V_{ERA} is greater than the write pass voltage V_{PASS}. The erase voltage V_{ERA} may have a magnitude similar to that of the program voltage V_{PGM}, and may be greater or smaller than the program voltage V_{PGM}. The sense amplifier module SAM connects the first bit line BL1 and the second bit line BL2, and applies the erase voltage V_{ERA} to these first bit line BL1 and second bit line BL2.

The voltage V_{SGD} is applied to the drain-side first select gate line SGD0 and the voltage V_{SGS} is applied to the source-side first select gate line SGS0 in the selected first divided block DBLK1. This causes Gate Induced Drain Leakage (GIDL) in the channel region of the drain-side select transistor STD corresponding to the drain-side first select gate line SGD0, and electron and hole pairs are generated. The electrons move to a bit line BL1 side, and the holes move to a memory cell MC side. The erase voltage V_{ERA} is transferred also from a source-side conductive layer 100.

The voltage V_{SS} is applied to the word line WL. This causes the holes diffused in the channel of the memory string MS to move to the electric charge accumulating film 132 (FIG. 10) via the tunnel insulating film 131 (FIG. 10), and the threshold of the memory cell MC decreases.

On the other hand, in the unselected second divided block DBLK2 side, the erase voltage V_{ERA} is applied to the drain-side second select gate line SGD1 and the source-side second select gate line SGS1. Therefore, the second divided block DBLK2 becomes a floating state, and the erase operation is not performed.

### Effects

As described above, according to the first embodiment, the drain-side select gate lines SGD0 and SGD1 and the source-side select gate lines SGS0 and SGS1 are divided in the X-direction, thereby enabling independently applying different voltages thereto. Therefore, by dividing the memory cell array MCA into two and setting the unselected regions in a floating state, the charge amount of the word line can be reduced, and the read performance, the write performance, and the erase performance can be improved.

Additionally, since the read unit, the write unit, and the erase unit can be finely set, unnecessary power consumption can be reduced when a user wants to perform an operation in a fine read unit.

### Second Embodiment

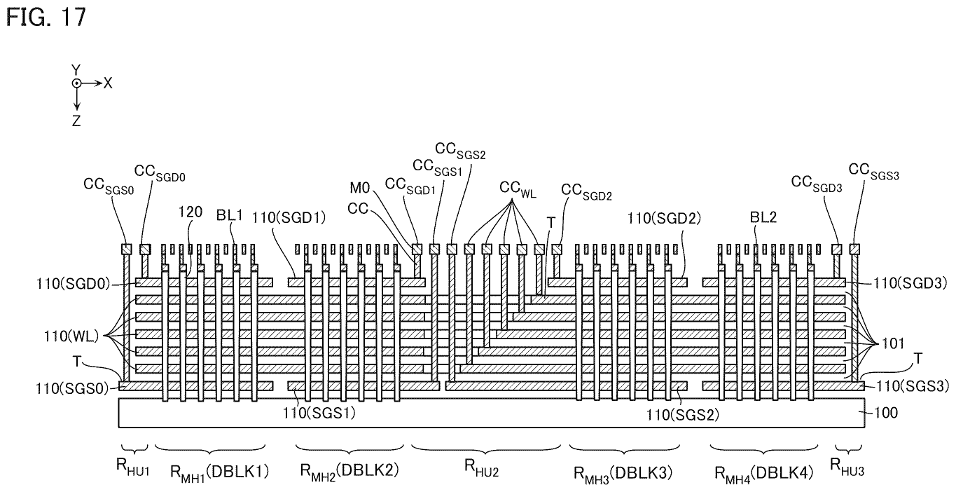

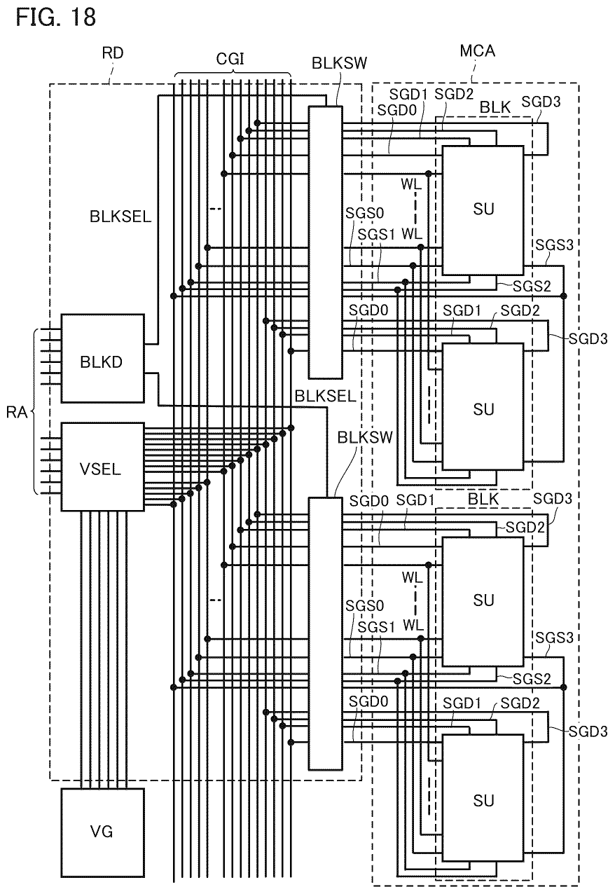

FIG. 17 is a cross-sectional view illustrating a schematic configuration of a semiconductor memory device according to a second embodiment. FIG. 17 corresponds to the memory cell array layer L_{MCA} in FIG. 8.

In the second embodiment, the memory cell array layer L_{MCA} is divided into four in the X-direction. More specifically, the memory cell array layer L_{MCA} includes a first memory region R_{MH1}, a second memory region R_{MH2}, a third memory region R_{MH3}, and a fourth memory region R_{MH4} arranged in the X-direction. The memory cell array layer L_{MCA} includes a first hook-up region R_{HU1} and a third hook-up region R_{HU3} at both ends in the X-direction. The memory cell array layer L_{MCA} includes a second hook-up region R_{HU2} between the second memory region R_{MH2} and the third memory region R_{MH3}.

In the first hook-up region R_{HU1}, the second hook-up region R_{HU2}, and the third hook-up region R_{HU3}, a terrace portion T formed in a staircase pattern is provided at a part of the plurality of conductive layers 110.

The uppermost conductive layer 110 (SGD) that functions as the drain-side select gate line SGD is divided in the X-direction between the first memory region R_{MH1} and the second memory region R_{MH2}, in the second hook-up region R_{HU2}, and between the third memory region R_{MH3} and the fourth memory region R_{MH4}. That is, the conductive layer 110 (SGD) includes a conductive layer 110 (SGD0) that functions as a drain-side first select gate line SGD0 of a first divided block DBLK1 positioned in the first memory region R_{MH1}, a conductive layer 110 (SGD1) that functions as a drain-side second select gate line SGD1 of a second divided block DBLK2 positioned in the second memory region R_{MH2}, a conductive layer 110 (SGD2) that functions as a drain-side third select gate line SGD2 of a third divided block DBLK3 positioned in the third memory region R_{MH3}, and a conductive layer 110 (SGD3) that functions as a drain-side fourth select gate line SGD3 of a fourth divided block DBLK4 positioned in the fourth memory region R_{MH4}.

The lowermost conductive layer 110 (SGS) that functions as the source-side select gate line SGS is divided in the X-direction between the first memory region R_{MH1} and the second memory region R_{MH2}, in the second hook-up region R_{HU2}, and between the third memory region R_{MH3} and the fourth memory region R_{MH4}. That is, the conductive layer 110 (SGS) includes a conductive layer 110 (SGS0) that functions as a source-side first select gate line SGS0 of the first divided block DBLK1 positioned in the first memory region R_{MH1}, a conductive layer 110 (SGS1) that functions as a source-side second select gate line SGS1 of the second divided block DBLK2 positioned in the second memory region R_{MH2}, a conductive layer 110 (SGS2) that functions as a source-side third select gate line SGS2 of the third divided block DBLK3 positioned in the third memory region R_{MH3}, and a conductive layer 110 (SGS3) that functions as a source-side fourth select gate line SGS3 of the fourth divided block DBLK4 positioned in the fourth memory region R_{MH4}.

In the hook-up region R_{HU1}, a plurality of via-contact electrodes CC_{SGD0} and CC_{SGS0} are provided. In the hook-up region R_{HU2}, a plurality of via-contact electrodes CC_{WL}, CC_{SGD1}, CC_{SGD2}, CC_{SGS1}, and CC_{SGS2} are provided. In the hook-up region R_{HU3}, a plurality of via-contact electrodes CC_{SGD3} and CC_{SGS3} are provided. These plurality of via-contact electrodes CC_{WL}, CC_{SGD0}, CC_{SGD1}, CC_{SGD2}, CC_{SGD3}, CC_{SGS0}, CC_{SGS1}, CC_{SGS2}, and CC_{SGS3} extend in the Z-direction and have lower ends connected to the terrace portions T of the conductive layers 110 (WL), 110 (SGD0), 110 (SGD1), 110 (SGD2), 110 (SGD3), 110 (SGS0), 110 (SGS1), 110 (SGS2), and 110 (SGS3), respectively.

FIG. 18 is a block diagram illustrating a schematic configuration of a row decoder RD used in this embodiment, and corresponds to FIG. 3.

In the row decoder RD in FIG. 3, in addition to the word line WL, the drain-side first select gate line SGD0, the drain-side second select gate line SGD2, the source-side first select gate line SGS0, and the source-side second select gate line SGS1 are connected to each of the memory blocks BLK. In this embodiment, further, the drain-side third select gate line SGD2, the drain-side fourth select gate line SGD3, the source-side third select gate line SGS2, and the source-side fourth select gate line SGS3 are connected to each of the memory blocks BLK. The wirings CGI are added by the number of the added select gate lines SGD and SGS.

According to the second embodiment, the charge amount of the word line can be further reduced, and the read performance, the write performance, and the erase performance can be further improved compared with the first embodiment. Additionally, since the read unit, the write unit, and the erase unit can be further finely set, the power consumption can be further reduced.

### Third Embodiment

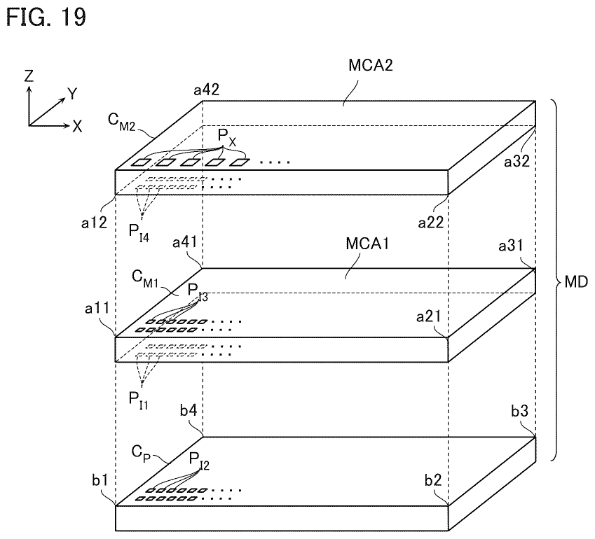

FIG. 19 is a schematic exploded perspective view illustrating an exemplary configuration of a semiconductor memory device according to the third embodiment. As illustrated in FIG. 19, the memory die MD includes a chip C_{M1} including a first memory cell array MCA1, a chip C_{M2} including a second memory cell array MCA2, and the chip C_{P} on the peripheral circuit PC side. While the memory die MD illustrated in FIG. 19 includes two layers of the chips C_{M1} and C_{M2}, the memory die MD may include three layers or more of chips C_{Mn}.

On an upper surface of the chip C_{M1}, a plurality of bonding electrodes P_{I3} are provided. On a lower surface of the chip C_{M1}, a plurality of bonding electrodes P_{I1} are provided. On an upper surface of the chip C_{M2}, a plurality of external pad electrodes P_{X} connectable to bonding wires (not illustrated) are provided. On a lower surface of the chip C_{M2}, a plurality of bonding electrodes P_{I4} are provided. On an upper surface of the chip C_{P}, a plurality of bonding electrodes P_{I2} are provided. Hereinafter, for the chips C_{M1} and C_{M2}, the surfaces on which the plurality of bonding electrodes P_{I1} and P_{I4} are provided are referred to as front surfaces, and the surfaces on which the plurality of bonding electrodes P_{I3} and the plurality of external pad electrodes P_{X} are provided are referred to as back surfaces. For the chip C_{P}, the surface on which the plurality of bonding electrodes P_{I2} are provided is referred to as a front surface, and the surface opposite to the front surface is referred to as a back surface.

The chip C_{M1} and the chip C_{P} are arranged such that the front surface of the chip C_{M1} faces the front surface of the chip C_{P}. The plurality of bonding electrodes P_{I1} are provided in correspondence with the plurality of bonding electrodes P_{I2}, and are arranged in positions where the plurality of bonding electrodes P_{I1} are allowed to be bonded to the plurality of bonding electrodes P_{I2}. The bonding electrode P_{I1} and the bonding electrode P_{I2} function as bonding electrodes for bonding the chip C_{M1} and the chip C_{P} and allowing electrical conduction.

The chip C_{M1} and the chip C_{M2} are arranged such that the back surface of the chip C_{M1} faces the front surface of the chip C_{M2}. The plurality of bonding electrodes P_{I4} are provided in correspondence with the plurality of bonding electrodes P_{I3}, and are arranged in positions where the plurality of bonding electrodes P_{I4} are allowed to be bonded to the plurality of bonding electrodes P_{I3}. The bonding electrode P_{I4} and the bonding electrode P_{I3} function as bonding electrodes for bonding the chip C_{M1} and the chip C_{M2} and allowing electrical conduction.

In the example in FIG. 19, corner portions a11, a21, a31, and a41 of the chip C_{M1} correspond to corner portions b1, b2, b3, and b4 of the chip C_{P}, respectively. Corner portions a12, a22, a32, and a42 of the chip C_{M2} correspond to the corner portions b1, b2, b3, and b4 of the chip C_{P}, respectively.

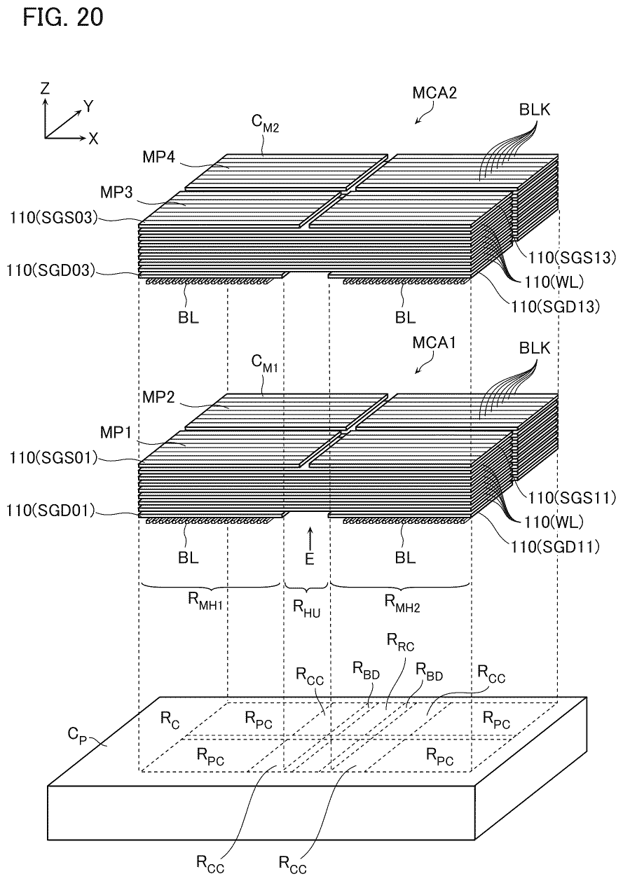

FIG. 20 is a schematic perspective view of the chip C_{M1}, the chip C_{M2}, and the chip C_{P}. FIG. 20 omits a part of the configuration such as the bonding electrodes P_{I1}.

### Structure of Chips C_{M1} and C_{M2}

In the example of FIG. 20, the chip C_{M1} includes two memory planes MP1 and MP2 arranged in the Y-direction. The chip C_{M2} includes two memory planes MP3 and MP4 arranged in the Y-direction. The memory planes MP1 and MP3 are stacked in the Z-direction, and under the same control. The memory planes MP2 and MP4 are stacked in the Z-direction, and under the same control. The four memory planes MP1, MP2, MP3, and MP4 may be each simply referred to as a memory plane MP. Each of these four memory planes MP1, MP2, MP3, and MP4 includes a plurality of memory blocks BLK arranged in the Y-direction. In the example of FIG. 20, each of these four memory planes MP1, MP2, MP3, and MP4 includes a first memory region R_{MH1} and a second memory region R_{MH2} provided on both sides in the X-direction, and a hook-up region R_{HU} provided between these first memory region R_{MH1} and second memory region R_{MH2}. In the example of FIG. 20, peripheral circuits provided around the memory cell arrays MCA1 and MCA2 are omitted.

In the illustrated example, the hook-up region R_{HU} is provided in the center portion in the X-direction of the memory plane MP. However, this configuration is only an example, and the specific configuration can be adjusted as appropriate. For example, the hook-up region R_{HU} may be provided not at the center portion in the X-direction but at both end portions in the X-direction of the memory plane MP.

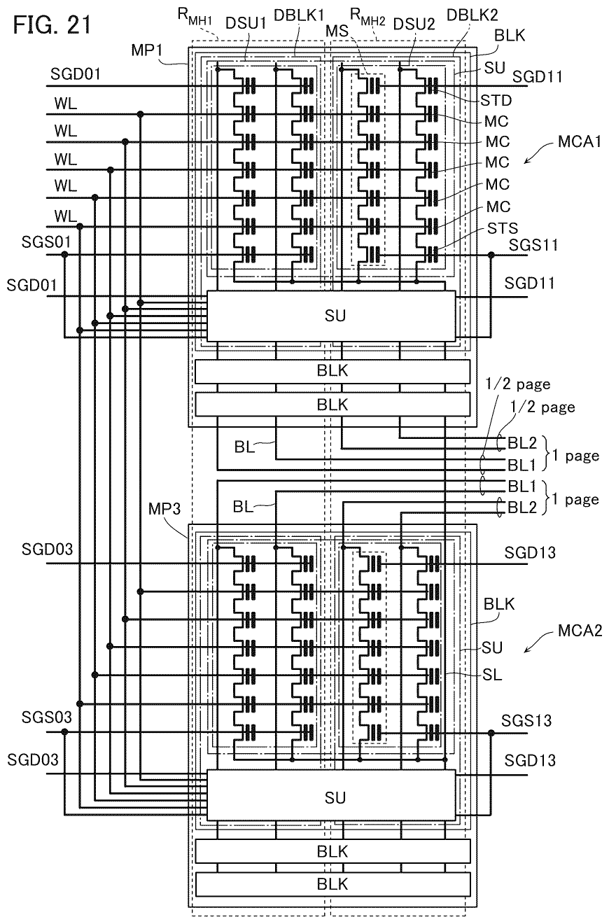

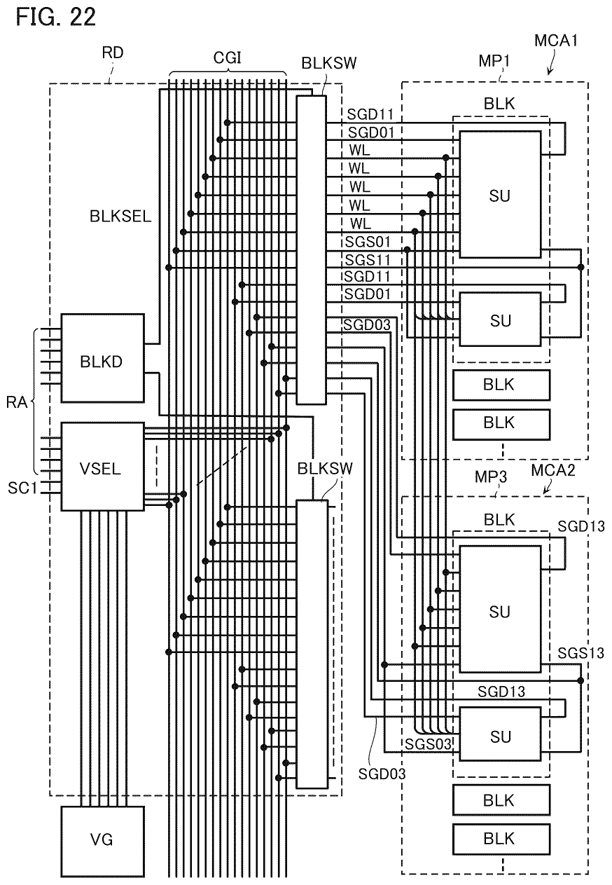

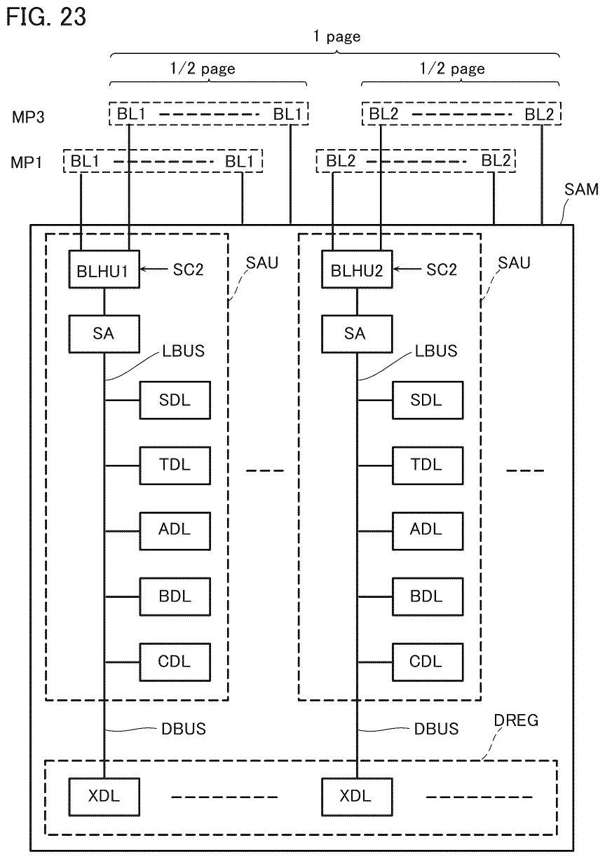

FIG. 21 is a schematic circuit diagram illustrating a configuration of a part of the memory die MD. FIG. 22 is a schematic circuit diagram illustrating a configuration of a row decoder RD. FIG. 23 is a schematic block diagram illustrating a configuration of a sense amplifier module SAM. While FIG. 21, FIG. 22, and FIG. 23 illustrate only the memory plane MP1 included in the memory cell array MCA1 and the memory plane MP3 included in the memory cell array MCA2, the memory planes MP2 and MP4 also can be similarly configured. In the following description, for configurations same as the configurations in FIG. 2, FIG. 3, and FIG. 4, the explanation is omitted.

As illustrated in FIG. 21, the memory cell array MCA1 and the memory cell array MCA2 stacked in the Z-direction are configured similarly to the memory cell array MCA illustrated in FIG. 2.

The memory planes MP1 and MP3 are each divided into a first memory region R_{MH1} and a second memory region R_{MH2} in an arrangement direction of a plurality of bit lines BL. Thus, each of the memory planes MP1 and MP3 includes a first divided block DBLK1 and a second divided block DBLK2, a first divided string unit DSU1 and a second divided string unit DSU2, and a first bit line BL1 and a second bit line BL2. Each of the memory planes MP1 and MP3 is able to perform an access in unit of 1 page and a read in unit of ½ page corresponding to the first divided string unit DSU1 and the second divided string unit DSU2.

A difference from the first embodiment is that the word lines WL of the corresponding memory blocks BLK in the memory plane MP1 and the memory plane MP3 stacked in the Z-direction are mutually connected in common.

A difference from the first embodiment is that the drain-side first select gate line SGD01, the drain-side second select gate line SGD11, a source-side first select gate line SGS01, and a source-side second select gate line SGS11 are connected to the memory plane MP1, a drain-side first select gate line SGD03, a drain-side second select gate line SGD13, a source-side first select gate line SGS03, and a source-side second select gate line SGS13 are connected to the memory plane MP3.

A difference from the first embodiment is that the bit lines BL are connected to the sense amplifier module SAM from each of the memory plane MP1 and the memory plane MP3.

As illustrated in FIG. 22, the row decoder RD applies predetermined voltages to the drain-side first select gate line SGD01, the drain-side second select gate line SGD11, the source-side first select gate line SGS01, and the source-side second select gate line SGS11 of the memory plane MP1, and additionally, applies predetermined voltages also to the drain-side first select gate line SGD03, the drain-side second select gate line SGD13, the source-side first select gate line SGS03, and the source-side second select gate line SGS13 of the memory plane MP3. Other configurations are similar to those of the first embodiment.

As illustrated in FIG. 23, the sense amplifier module SAM includes a bit line hook-up circuit BLHU1 that switches the first bit line BL1 of the memory plane MP1 and the first bit line BL1 of the memory plane MP3 based on the divided block selection signal SC2 output from the sequencer SQC, and a bit line hook-up circuit BLHU2 that switches the second bit line BL2 of the memory plane MP1 and the second bit line BL2 of the memory plane MP3 based on the divided block selection signal SC2 output from the sequencer SQC. The bit line hook-up circuits BLHU1 and BLHU2 select one of eight combinations in total including four combinations in the case of ½ page of read or write and four combinations in the case of 1 page of read or write as the connection mode to the bit line BL.

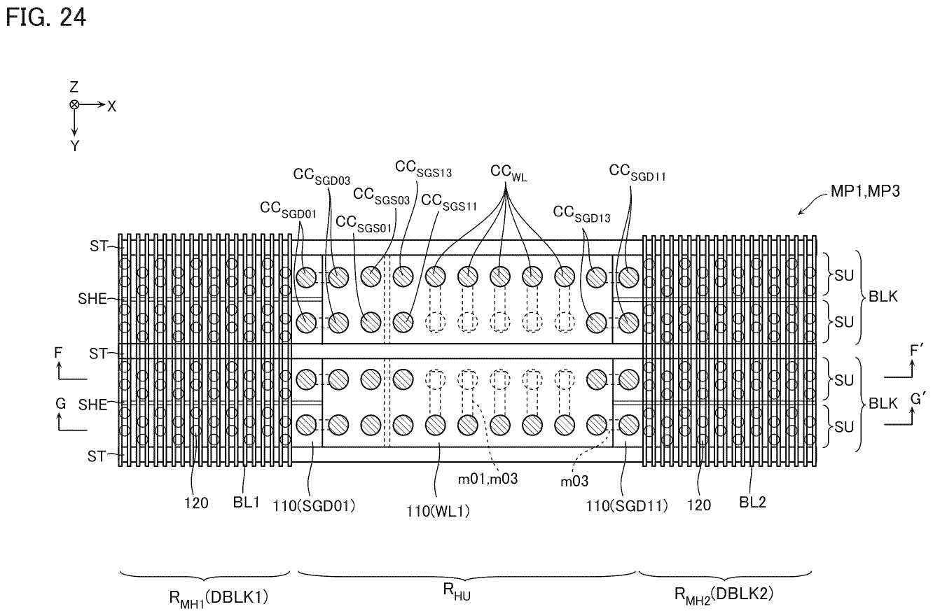

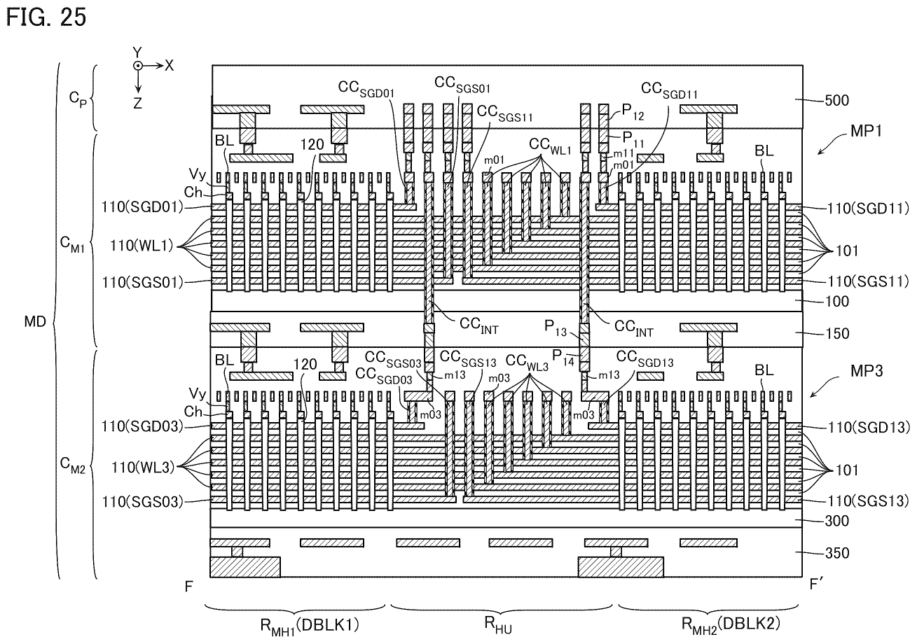

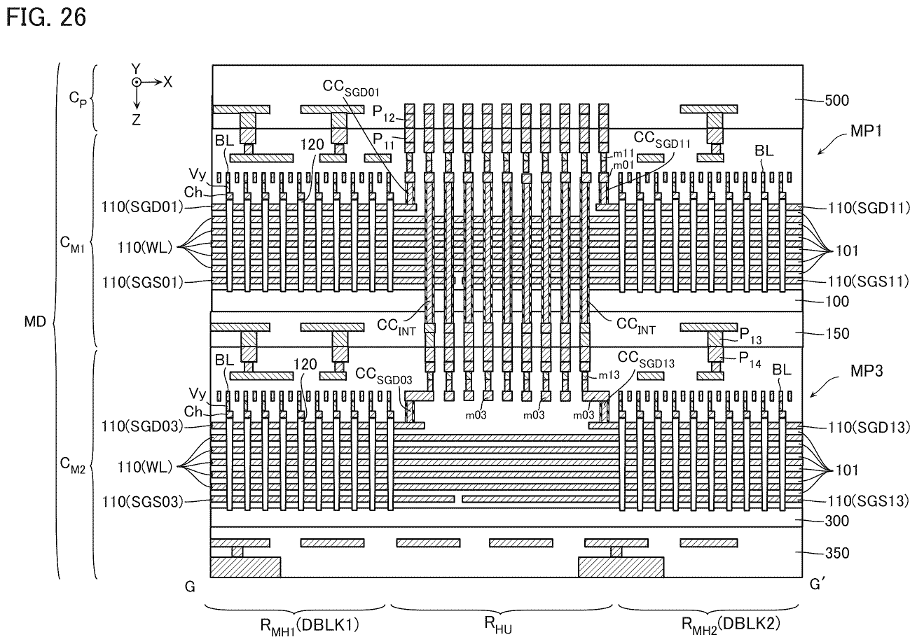

Next, a structure of the memory die MD according to this embodiment is described. FIG. 24 is a schematic bottom view illustrating a configuration of a part of the chips C_{M1} and C_{M2} when viewed in a direction of an arrow E in FIG. 20. FIG. 25 is a schematic cross-sectional view of a part of the chips C_{M1} and C_{M2} taken along line F-F′ and viewed in an arrow direction in FIG. 24. FIG. 26 is a schematic cross-sectional view of a part of the chips C_{M1} and C_{M2} taken along line G-G′ and viewed in an arrow direction in FIG. 24.

As illustrated in FIG. 24, the memory planes MP1 and MP3 include a plurality of memory blocks BLK arranged in the Y-direction. Each of the memory blocks BLK includes a plurality of (two, in this example) string units SU arranged in the Y-direction. In the hook-up region R_{HU}, a plurality of via-contact electrodes CC are provided for each memory block BLK. The hook-up region R_{HU} includes via-contact electrodes CC in two rows in the Y-direction corresponding to the string units SU. The first row corresponding to the line G-G′ includes via-contact electrodes CC_{SGD01}, CC_{SGD03}, CC_{SGS03}, CC_{SGS13}, CC_{WL}, CC_{SGD13}, and CC_{SGD11} arranged in the X-direction. The second row corresponding to the line F-F′ includes via-contact electrodes CC_{SGD01}, CC_{SGD03}, CC_{SGS01}, CC_{SGS11}, CC_{SGD13}, and CC_{SGD11}. These via-contact electrodes CC correspond to all voltages to be applied from the chip C_{P} side to one memory block BLK of the memory planes MP1 and MP3.

As illustrated in FIG. 25, the configuration of the chip C_{P} and the chip C_{M1} is approximately similar to the configuration of the first embodiment illustrated in FIG. 8. The chip C_{P} has an insulating layer 500. The chip C_{M1} has a conductive layer 100 and an insulating layer 150 at the chip C_{M2} side. The chip C_{M2} is approximately similar to the chip C_{M1}. The chip C_{M2} has a conductive layer 300 and an insulating layer 350 at the opposite side to the chip C_{M1}. In this embodiment, among a plurality of conductive layers 110 constituting the memory plane MP1 included in the chip C_{M1}, the uppermost conductive layers 110 are a conductive layer 110 (SGD01) constituting the drain-side first select gate line SGD01 and a conductive layer 110 (SGD11) constituting the drain-side second select gate line SGD11 in the memory plane MP1. In this embodiment, among the plurality of conductive layers 110 constituting the memory plane MP1 included in the chip C_{M1}, the intermediate conductive layers 110 are conductive layers 110 (WL1) constituting the word lines WL1 in the memory plane MP1. In this embodiment, among the plurality of conductive layers 110 constituting the memory plane MP1 included in the chip C_{M1}, the lowermost conductive layers 110 are a conductive layer 110 (SGS01) constituting the source-side first select gate line SGS01 and a conductive layer 110 (SGS11) constituting the source-side second select gate line SGS11 in the memory plane MP1.

In this embodiment, among a plurality of conductive layers 110 constituting the memory plane MP3 included in the chip C_{M2}, the uppermost conductive layers 110 are a conductive layer 110 (SGD03) constituting the drain-side first select gate line SGD03 and a conductive layer 110 (SGD13) constituting the drain-side second select gate line SGD13 in the memory plane MP3. In this embodiment, among the plurality of conductive layers 110 constituting the memory plane MP3 included in the chip C_{M2}, the intermediate conductive layers 110 are conductive layers 110 (WL3) constituting the word lines WL3 in the memory plane MP3. In this embodiment, among the plurality of conductive layers 110 constituting the memory plane MP3 included in the chip C_{M2}, the lowermost conductive layers 110 are a conductive layer 110 (SGS03) constituting the source-side first select gate line SGS03 and a conductive layer 110 (SGS13) constituting the source-side second select gate line SGS13 in the memory plane MP3.

As illustrated in FIG. 25, the via-contact electrodes CC_{SGD01}, CC_{SGD11}, CC_{SGS01}, and CC_{SGS11} connected to the conductive layers 110 (SGD01), 110 (SGD11), 110 (SGS01), and 110 (SGS11) of the memory plane MP1 of the chip C_{M1}, respectively are each connected to the bonding electrode P₁₁ via wirings m01 and m11. The via-contact electrode CC_{SGD03} connected to the conductive layer 110 (SGD03) of the memory plane MP3 is connected to the bonding electrode P₁₁ of the chip C_{M1} via wirings m03 and m13, bonding electrodes P₁₄ and P₁₃, an intermediate via-contact electrode CC_{INT} penetrating the chip C_{M1} in the Z-direction, and the wirings m01 and m11. The via-contact electrode CC_{SGD13} connected to the conductive layer 110 (SGD13) of the memory plane MP3 is connected to the bonding electrode P₁₁ of the chip C_{M1} via the wirings m03 and m13, the bonding electrodes P₁₄ and P₁₃, the intermediate via-contact electrode CC_{INT} penetrating the chip C_{M1} in the Z-direction, and the wirings m01 and m11. In the memory plane MP1, spaces are provided in the X-direction between the via-contact electrode CC_{SGD01} and the via-contact electrode CC_{SGS01}, and between a via-contact electrode CC_{WL1} and the via-contact electrode CC_{SGD11}, and the intermediate via-contact electrodes CC_{INT} are provided at the respective spaces.

Therefore, in the second row indicated by the line F-F′ in FIG. 24, the six via-contact electrodes CC_{SGD01}, CC_{SGD03}, CC_{SGS01}, CC_{SGS11}, CC_{SGD11}, and CC_{SGD13} are connected to the chip C_{P} via the bonding electrodes P₁₁ and P₁₂.

As illustrated in FIG. 26, the via-contact electrodes CC_{SGD01} and CC_{SGD11} connected to the conductive layers 110 (SGD01) and 110 (SGD11) of the memory plane MP1 of the chip C_{M1}, respectively are each connected to the bonding electrode P₁₁ via the wirings m01 and m11. The via-contact electrode CC_{WL1} connected to the conductive layer 110 (WL1) of the memory plane MP1 illustrated in FIG. 25 is connected to an upper end of the intermediate via-contact electrode CC_{INT} penetrating the chip C_{M1} in the Z-direction illustrated in FIG. 26 via the wiring m01 extending in the Y-direction. The via-contact electrode CC_{WL3} connected to the conductive layer 110 (WL3) and the via-contact electrodes CC_{SGS03} and CC_{SGS13} connected to the conductive layers 110 (SGS03) and 110 (SGS13) of the memory plane MP3 illustrated in FIG. 25 are connected to a lower end of the intermediate via-contact electrode CC_{INT} penetrating the chip C_{M1} in the Z-direction illustrated in FIG. 26 via the wiring m03 extending in the Y-direction.

As illustrated in FIG. 26, the upper end of the intermediate via-contact electrode CC_{INT} is connected to the bonding electrode P₁₁ via the wirings m01 and m11. Therefore, in the first row indicated by the line G-G′ in FIG. 24, the eleven via-contact electrodes in total including CC_{SGD01}, CC_{SGD03}, CC_{SGS03}, CC_{SGS13}, five CC_{WL}, CC_{SGD13}, and CC_{SGD11} are connected to the chip C_{P} via the bonding electrodes P₁₁ and P₁₂.

### Operations

Next, operations of the memory die MD according to the third embodiment is described.

### Read Operation

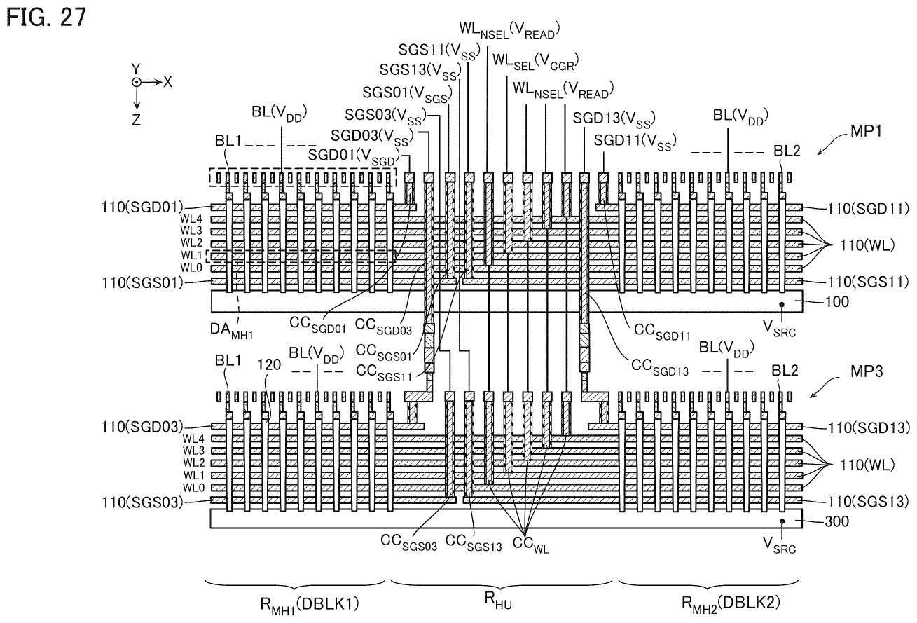

FIG. 27 illustrates a main part of the memory die MD of FIG. 25, and is a diagram schematically illustrating voltages applied to respective portions of the memory planes MP1 and MP2 in a read operation. To simplify the explanation, details of the voltage application timing are omitted.

First, a case of reading ½ page of data DA_{MH1} stored in the memory cell MC connected to the word line WL1 of the first divided block DBLK1 of the memory plane MP1 from the first bit line BL1 is described.

When a command to read the data from the memory cell MC connected to the word line WL1 of the first divided block DBLK1 is input, the sequencer SQC (FIG. 1) sets the divided block selection signals SC1 and SC2 to a signal level for selecting the first divided block DBLK1. A voltage V_{SRC} is applied to conductive layers 100 and 300 that function as the source lines. The voltage V_{SRC} is greater than the ground voltage V_{SS}, but approximately equal to the ground voltage V_{SS}. A voltage V_{DD} is charged to the first bit line BL1 and the second bit line BL2 of the memory plane MP1 and the first bit line BL1 and the second bit line BL2 of the memory plane MP2 via the sense amplifier module SAM.

The voltage V_{SGD} is applied to the drain-side first select gate line SGD01 and the voltage V_{SGS} is applied to the source-side first select gate line SGS01 in the selected first divided block DBLK1. The voltage V_{SGD} is a gate voltage that is greater than the voltage V_{SS} and turns ON the drain-side select transistor STD. The voltage V_{SGS} is a gate voltage that is greater than the voltage V_{SS} and turns ON the source-side select transistor STS. The voltage V_{SGD} and the voltage V_{SGS} may be same, or may be different.

The voltage V_{CGR} in a threshold level of binary or more is applied in phases to a selected word line WL_{SEL} connected to the memory cell MC from which the data is read. On the other hand, the voltage V_{READ} is applied to unselected word lines WL_{NSEL} connected to the memory cells MC from which the data is not read. The voltage V_{READ} is a voltage that is greater than the voltage V_{CGR}, and constantly turns ON the memory cell MC regardless of the value of the data stored in the memory cell MC.

When the above-described respective voltages are applied to the word lines WL and the select gate lines SGD01 and SGS01, the select transistors STD and STS connected to the selected string unit SU turn ON. All the memory cells MC connected to the unselected word lines WL_{NSEL} turn ON. Among the memory cells MC connected to the selected word line WL_{SEL}, the selected memory cells MC in the threshold level greater than that of the voltage V_{CGR} turn OFF, therefore, the voltage of the first bit line BL1 keeps the voltage V_{DD}. Meanwhile, among the memory cells MC connected to the selected word line WL_{SEL}, the selected memory cells MC in the threshold level smaller than that of the voltage V_{CGR} turn ON, therefore, the voltage V_{DD} of the first bit line BL1 is discharged to the conductive layer 100 side via the drain-side select transistor STD, the memory cell MC, and the source-side select transistor STS, and drops to the voltage V_{SS}. By detecting these voltage states of the first bit line BL1 with the sense amplifier module SAM, ½ page of read data DA_{MH1} can be read into the latch circuit XDL.

On the other hand, the voltage V_{SS} (or a voltage greater than the voltage V_{SS} and close to the voltage V_{SS}) is applied to the drain-side first select gate line SGD03, the drain-side second select gate lines SGD11 and SGD13, the source-side first select gate line SGS03, and the source-side second select gate lines SGS11 and SGS13 in the unselected second divided block DBLK2 side of the memory planes MP1 and MP3 and the unselected first divided block DBLK1 side of the memory plane MP3. The voltage V_{SS} is a gate voltage that does not turn ON either the drain-side select transistor STD or the source-side select transistor STS. Thus, the second divided block DBLK2 of the memory planes MP1 and MP3 and the first divided block DBLK1 of the memory plane MP3 become a floating state. Therefore, charging to the conductive layer 110 positioned in the second memory region R_{MH2} of the memory planes MP1 and MP3, and the first memory region R_{MH1} of the memory plane MP3 is not performed.

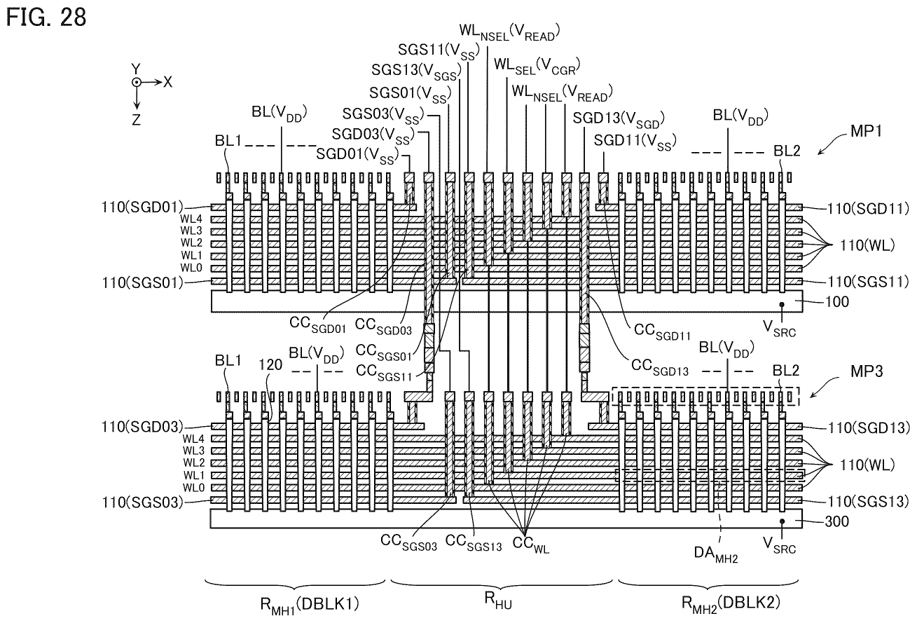

FIG. 28 is a diagram for describing another read operation. Here, a case of reading ½ page of data DA_{MH2} stored in the memory cell MC connected to a word line WL1 of the second divided block DBLK2 of the memory plane MP3 from the second bit line BL2 is described. The explanation of parts overlapping with the explanation of FIG. 27 is omitted.

When a command to read the data from the memory cell MC connected to the word line WL1 of the second divided block DBLK2 of the memory plane MP3 is input, the sequencer SQC (FIG. 1) sets the divided block selection signals SC1 and SC2 to a signal level for selecting the second divided block DBLK2 of the memory plane MP3. A voltage V_{SRC} is applied to the conductive layers 100 and 300 that function as the source lines. A voltage V_{DD} is charged to the first bit line BL1 and the second bit line BL2 of the memory plane MP1 and the first bit line BL1 and the second bit line BL2 of the memory plane MP3 via the sense amplifier module SAM.

The voltage V_{SGD} is applied to the drain-side second select gate line SGD13 and the voltage V_{SGS} is applied to the source-side second select gate line SGS13 in the selected second divided block DBLK2 of the memory plane MP3.

The voltage V_{CGR} in a threshold level of binary or more is applied in phases to a selected word line WL_{SEL} connected to the memory cell MC from which the data is read. On the other hand, the voltage V_{READ} is applied to unselected word lines WL_{NSEL} connected to the memory cells MC from which the data is not read.

The operation in the second divided block DBLK2 of the memory plane MP3 when the above-described respective voltages are applied to the word lines WL and the select gate lines SGD1 and SGS1 is similar to the operation in the first divided block DBLK1 of the memory plane MP1 in FIG. 27. Thus, ½ page of read data DA_{MH2} can be read into the latch circuit XDL.

On the other hand, the voltage V_{SS} (or a voltage greater than the voltage V_{SS} and close to the voltage V_{SS}) is applied to the drain-side first select gate lines SGD01 and SGD03, the drain-side second select gate line SGD11, the source-side first select gate lines SGS01 and SGS03, and the source-side second select gate line SGS11 in the unselected first divided block DBLK1 side of the memory planes MP1 and MP3 and the unselected second divided block DBLK2 side of the memory plane MP1. Thus, the first divided block DBLK1 of the memory planes MP1 and MP3 and the second divided block DBLK2 of the memory plane MP1 become a floating state. Therefore, charging to the conductive layer 110 positioned in the first memory region R_{MH1} of the memory planes MP1 and MP3, and the second memory region R_{MH2} of the memory plane MP1 is not performed.

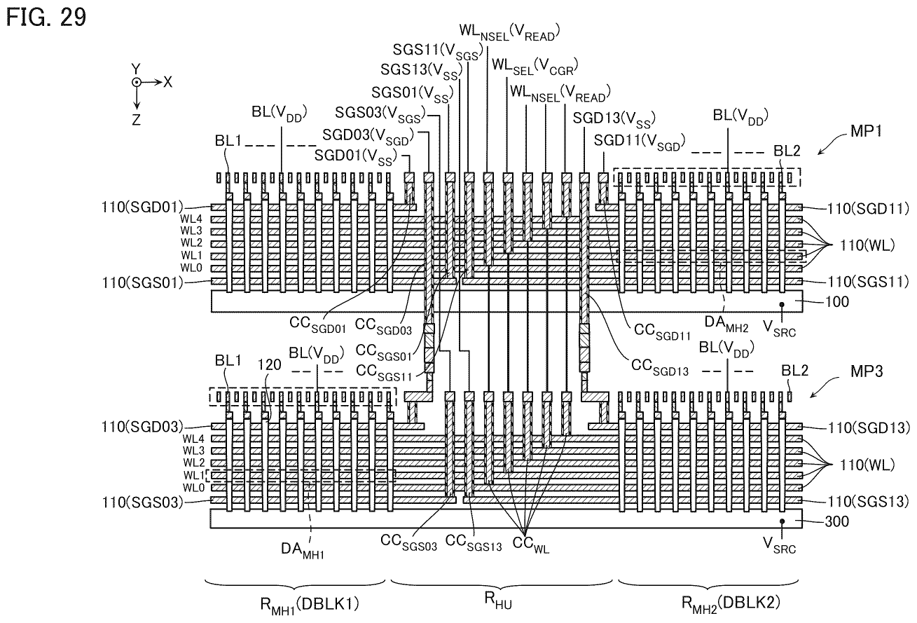

FIG. 29 is a diagram for describing still another read operation. Here, a case of reading 1 page of data DA stored in the memory cells MC connected to word lines WL1 of the second divided block DBLK2 of the memory plane MP1 and the first divided block DBLK1 of the memory plane MP3 from the first bit line BL1 and the second bit line BL2 is described. The explanation of parts overlapping with the explanation of FIG. 27 and FIG. 28 is omitted.

When a command to read ½ page of data from each of the second divided block DBLK2 of the memory plane MP1 and the first divided block DBLK1 of the memory plane MP3, that is, 1 page of data in total, is input, the sequencer SQC (FIG. 1) sets the divided block selection signals SC1 and SC2 to a signal level for selecting the second divided block DBLK2 of the memory plane MP1 and the first divided block DBLK1 of the memory plane MP3. A voltage V_{SRC} is applied to the conductive layers 100 and 300 that function as the source lines. A voltage V_{DD} is charged to the first bit line BL1 and the second bit line BL2 of the memory plane MP1 and the first bit line BL1 and the second bit line BL2 of the memory plane MP3 via the sense amplifier module SAM.

The voltage V_{SGD} is applied to the drain-side first select gate line SGD03 and the drain-side second select gate line SGD11, and the voltage V_{SGS} is applied to the source-side first select gate line SGS03 and the source-side second select gate line SGS11 in the selected first divided block DBLK1 of the memory plane MP3 and the selected second divided block DBLK2 of the memory plane MP1.

The voltage V_{CGR} in a threshold level of binary or more is applied in phases to a selected word line WL_{SEL} connected to the memory cell MC from which the data is read. On the other hand, the voltage V_{READ} is applied to unselected word lines WL_{NSEL} connected to the memory cells MC from which the data is not read.

Thus, respective ½ page of data DA_{MH1} and DA_{MH2} can be read from the selected second divided block DBLK2 of the memory plane MP1 and the selected first divided block DBLK1 of the memory plane MP3.

On the other hand, the voltage V_{SS} (or a voltage greater than the voltage V_{SS} and close to the voltage V_{SS}) is applied to the drain-side first select gate line SGD01, the drain-side second select gate line SGD13, the source-side first select gate line SGS01, and the source-side second select gate line SGS13 in the unselected first divided block DBLK1 of the memory plane MP1 and the unselected second divided block DBLK2 of the memory plane MP3. Thus, the first divided block DBLK1 of the memory plane MP1 and the second divided block DBLK2 of the memory plane MP3 become a floating state. Therefore, charging to the conductive layers 110 positioned in these divided blocks DBLK is not performed.

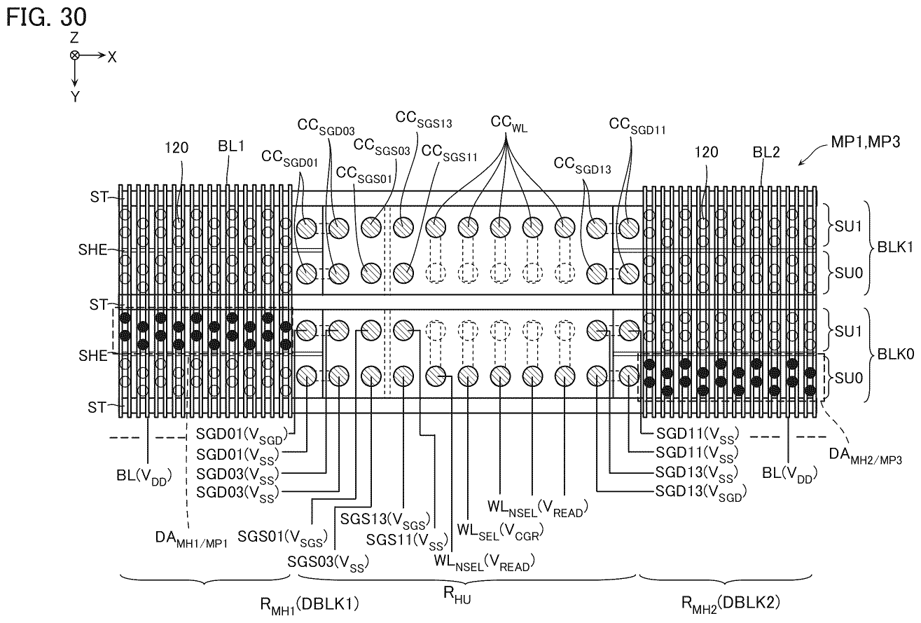

FIG. 30 is a diagram for describing still another read operation. Here, an example of simultaneously reading 1 page of data DA from the different string units SU0 and SU1 of the different memory planes MP1 and MP3 is described. FIG. 30 corresponds to FIG. 24.

In this example, the first divided block DBLK1 is selected in the memory plane MP1, and the second divided block DBLK2 is selected in the memory plane MP3. The string unit SU1 is selected in the first divided block DBLK1 of the memory plane MP1, and the string unit SU0 is selected in the second divided block DBLK2 of the memory plane MP3.

In the first divided block DBLK1 of the memory plane MP1, the voltage V_{SS} is applied to the drain-side first select gate line SGD01 connected to the string unit SU0, and the voltage V_{SGD} is applied to the drain-side first select gate line SGD01 connected to the string unit SU1. The voltage V_{SGS} is applied to the source-side first select gate line SGS01.

In the first divided block DBLK1 of the memory plane MP3, the voltage V_{SS} is applied to the drain-side first select gate line SGD03 connected to the string unit SU0, and the voltage V_{SS} is applied to the drain-side first select gate line SGD03 connected to the string unit SU1. The voltage V_{SS} is applied to the source-side first select gate line SGS03.

On the other hand, in the second divided block DBLK2 of the memory plane MP1, the voltage V_{SS} is applied to the drain-side second select gate line SGD11 connected to the string unit SU0, and the voltage V_{SS} is applied to the drain-side second select gate line SGD11 connected to the string unit SU1. The voltage V_{SS} is applied to the source-side second select gate line SGS11.

Further, in the second divided block BLK2 of the memory plane MP3, the voltage V_{SGD} is applied to the drain-side second select gate line SGD13 connected to the string unit SU0, and the voltage V_{SS} is applied to the drain-side second select gate line SGD13 connected to the string unit SU1. The voltage V_{SGS} is applied to the source-side second select gate line SGS13.

Thus, respective ½ page of data DA_{MH1/MP1} and DA_{MH2/MP3} are read from the string unit SU1 in the first divided block DBLK1 of the memory plane MP1 and from the string unit SU0 in the second divided block DBLK2 of the memory plane MP3.

### Write Operation

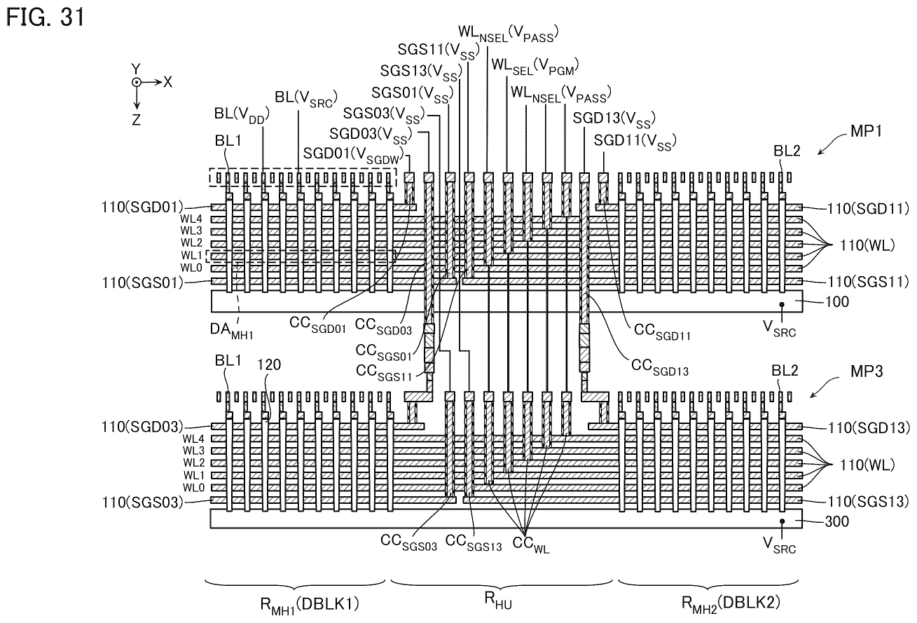

FIG. 31 illustrates the main part of the memory die MD in FIG. 25, and is a diagram schematically illustrating voltages applied to respective portions in a write operation of the memory die MD according to the third embodiment. To simplify the explanation, details of the voltage application timing are omitted.

Here, a case of writing ½ page of the data DA_{MH1} on the memory cell MC connected to the word line WL1 of the first divided block DBLK1 of the memory plane MP1 via the first bit line BL1 is described.

When a command to write the data on the memory cell MC connected to the word line WL1 of the first divided block DBLK1 of the memory plane MP1 is input, the sequencer SQC (FIG. 1) sets the divided block selection signals SC1 and SC2 to a signal level for selecting the first divided block DBLK1 of the memory plane MP1. The voltage V_{SRC} is applied to the conductive layers 100 and 300 that function as the source lines. The voltage V_{DD} or V_{SRC} corresponding to the write data is applied to the first bit line BL1 of the memory plane MP1 via the sense amplifier module SAM. That is, the voltage V_{SRC} is applied to the first bit line BL1 connected to the memory cell MC in which the threshold is increased, and the voltage V_{DD} is applied to the first bit line BL1 connected to the memory cell MC in which the threshold is not varied.

A voltage V_{SGDW} is applied to the drain-side first select gate line SGD01 and the voltage V_{SS} is applied to the source-side first select gate line SGS01 in the selected first divided block DBLK1 of the memory plane MP1. The voltage V_{SGDW} is greater than the voltages V_{SRC} and V_{DD}. The voltage V_{SGDW} is a voltage that turns ON the drain-side select transistor STD connected to the first bit line BL1 to which the voltage V_{SRC} is applied and does not turn ON the drain-side select transistor STD connected to the first bit line BL1 to which the voltage V_{DD} is applied.

The program voltage V_{PGM} is applied to the selected word line WL_{SEL} connected to the memory cell MC on which the data is written, and a write pass voltage V_{PASS} is applied to the unselected word line WL_{NSEL} connected to the memory cell MC on which the data is not written. The program voltage V_{PGM} is greater than the write pass voltage V_{PASS}. The write pass voltage V_{PASS} is a voltage that turns ON the memory cell MC.

When the respective voltages are applied to the word lines WL and the select gate lines SGD01 and SGS01, the source-side select transistor STS turns OFF, and therefore, the memory cell MC is disconnected from the conductive layer 100.

When the voltage applied to the first bit line BL1 is the voltage V_{SRC}, the drain-side select transistor STD connected to this first bit line BL1 turns ON, and the voltage V_{SRC} is transferred to the channel formed at the memory string MS. Meanwhile, when the voltage applied to the first bit line BL1 is the voltage V_{DD}, the drain-side select transistor STD connected to this first bit line BL1 turns OFF, and the channel formed at the memory string MS becomes a floating state.

When the program voltage V_{PGM} is applied to the selected word line WL_{SEL} in this state, in the memory cell MC having the channel to which the voltage V_{SRC} has been transferred, the electrons move from the channel to the electric charge accumulating film 132 (FIG. 10) via the tunnel insulating film 131 (FIG. 10), and the threshold voltage of the memory cell MC increases. Since a write verify operation is similar to the read operation illustrated in FIG. 27, the explanation is omitted here. Meanwhile, in the memory cell MC having the channel to which the voltage V_{SRD} has not been transferred, the channel is boosted and the electrons do not move. Thus, ½ page of the data DA_{MH1} stored in the latch circuit XDL can be written on the memory cell MC of the first divided block DBLK1 of the memory plane MP1.

On the other hand, in the unselected second divided block DBLK2 side of the memory planes MP1 and MP3 and the unselected first divided block DBLK1 side of the memory plane MP2, the voltage V_{SS} (or a voltage greater than the voltage V_{SS} and close to the voltage V_{SS}) is applied to the drain-side first select gate line SGD03, the drain-side second select gate lines SGD11 and SGD13, the source-side first select gate line SGS03, and the source-side second select gate lines SGS11 and SGS13. Therefore, the unselected second divided block DBLK2 of the memory planes MP1 and MP3 and the unselected first divided block DBLK1 of the memory plane MP2 become a floating state, and the write operation is not performed.

### Erase Operation

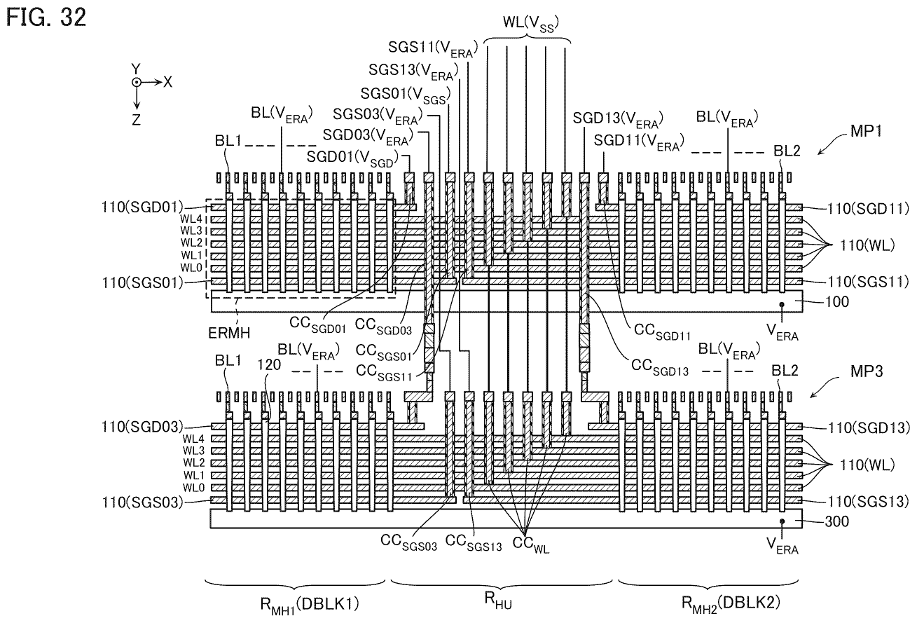

FIG. 32 illustrates the main part of the memory die MD in FIG. 25, and is a diagram schematically illustrating voltages applied to respective portions in an erase operation of the memory die MD according to the third embodiment. To simplify the explanation, details of the voltage application timing are omitted.

Here, a case where the first divided block DBLK1 of the memory plane MP1 is assumed to be an erase target memory portion ERMH is described.

When a command to erase the first divided block DBLK1 of the memory plane MP1 is input, the sequencer SQC (FIG. 1) sets the divided block selection signals SC1 and SC2 to a signal level for selecting the first divided block DBLK1 of the memory plane MP1. The erase voltage V_{ERA} is applied to the conductive layers 100 and 300 that function as the source lines. The erase voltage V_{ERA} is greater than the write pass voltage V_{PASS}. The erase voltage V_{ERA} may have a magnitude similar to that of the program voltage V_{PGM}, and may be greater or smaller than the program voltage V_{PGM}. The sense amplifier module SAM connects the first bit line BL1 and the second bit line BL2 of the memory planes MP1 and MP2, and applies the erase voltage V_{ERA} to these first bit line BL1 and second bit line BL2.

The voltage V_{SGD} is applied to the drain-side first select gate line SGD01 and the voltage V_{SGS} is applied to the source-side first select gate line SGS01 in the selected first divided block DBLK1 of the memory plane MP1. This causes GIDL in the channel region of the drain-side select transistor STD corresponding to the drain-side first select gate line SGD01, and electron and hole pairs are generated. The electrons move to the bit line BL1 side, and the holes move to the memory cell MC side. The erase voltage V_{ERA} is transferred also from the source-side conductive layer 100.

The voltage V_{SS} is applied to the word line WL. This causes the holes diffused in the channel of the memory string MS to move to the electric charge accumulating film 132 (FIG. 10) via the tunnel insulating film 131 (FIG. 10), and the threshold of the memory cell MC decreases.

On the other hand, in the unselected second divided block DBLK2 side of the memory planes MP1 and MP3 and the unselected first divided block DBLK1 side of the memory plane MP3, the erase voltage V_{ERA} is applied to the drain-side first select gate line SGD03, the drain-side second select gate lines SGD11 and SGD13, the source-side first select gate line SGS03, and the source-side second select gate lines SGS03 and SGS13. Therefore, the second divided block DBLK2 of the memory planes MP1 and MP3 and the first divided block DBLK1 of the memory plane MP3 become a floating state, and the erase operation is not performed.

### Effects

As described above, according to the third embodiment, the drain-side select gate lines SGD0 and SGD1 and the source-side select gate lines SGS0 and SGS1 of a plurality of memory planes MP are divided in the X-direction, thereby enabling independently applying different voltages thereto. Therefore, by dividing the memory cell array MCA into four or more, reading only a part thereof to use the part as a target of write and the like, and setting the other unselected regions in a floating state, the charge amount of the word line can be further reduced, and the read performance, the write performance, and the erase performance can be improved.

Additionally, since the read unit, the write unit, and the erase unit can be further finely set, unnecessary power consumption can be reduced when a user wants to perform an operation in a fine read unit.

### Fourth Embodiment

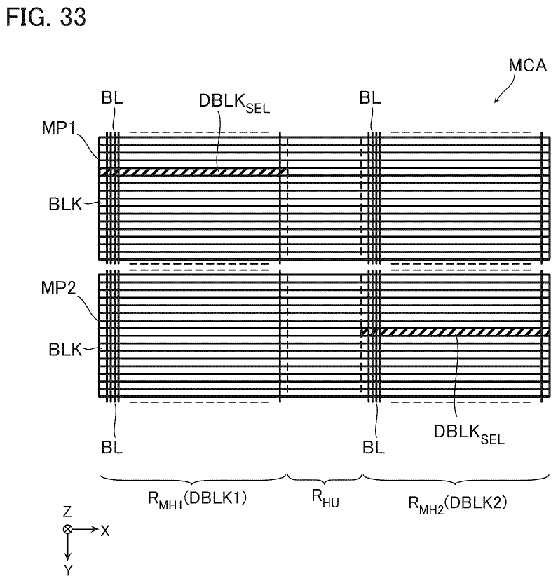

FIG. 33 is a diagram for describing a semiconductor memory device according to a fourth embodiment. FIG. 33 is a schematic plan view of the semiconductor memory device when viewed in a direction of an arrow E in FIG. 20.

As illustrated in FIG. 33, a memory cell array MCA includes a memory plane MP1 and a memory plane MP2. As illustrated in also FIG. 19, the memory planes MP1 and MP2 are controlled by mutually different row decoders RD. In this case, a selected divided block DBLK_{SEL} in the first divided block DBLK1 of the memory plane MP1 and a selected divided block DBLK_{SEL} in the second divided block DBLK2 of memory plane MP2 can be selected from different memory blocks BLK. This allows simultaneously reading and writing data in different memory blocks BLK, thus improving read and write efficiency.

### Others

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor memory device comprising:
a semiconductor substrate; and
a memory cell array arranged at one side in a first direction intersecting with the semiconductor substrate with respect to the semiconductor substrate, wherein
the memory cell array includes:
a plurality of conductive layers extending in a second direction intersecting with the first direction and arranged in the first direction;
a plurality of semiconductor layers extending in the first direction, arranged in a direction intersecting with the first direction, and facing the plurality of conductive layers;
respective gate insulating films provided between the plurality of semiconductor layers and the plurality of conductive layers; and
a plurality of wirings extending in a third direction intersecting with the first direction and the second direction, arranged in the second direction, and electrically connected to one end side in the first direction of the semiconductor layers,
the memory cell array includes a first region and a second region arranged in the second direction,
the plurality of conductive layers include:
a first conductive layer closest to the semiconductor substrate;
a second conductive layer farthest from the semiconductor substrate; and
a third conductive layer provided between the first conductive layer and the second conductive layer,
the first conductive layer is divided in the second direction to constitute a first divided layer positioned in the first region and a second divided layer positioned in the second region,
the second conductive layer is divided in the second direction to constitute a third divided layer positioned in the first region and a fourth divided layer positioned in the second region,
the third conductive layer is continuous over the first region and the second region, and
the plurality of wirings include a first wiring positioned in the first region and a second wiring positioned in the second region.

2. The semiconductor memory device according to claim 1, wherein
the memory cell array includes a third region arranged in the second direction with the first region and the second region, and
the memory cell array further includes a plurality of contact electrodes extending in the first direction in the third region, the plurality of contact electrodes have respective one ends electrically connected to the first divided layer, the second divided layer, the third divided layer, the fourth divided layer, and the third conductive layer, and the plurality of contact electrodes have respective the other ends electrically connected to the semiconductor substrate.

3. The semiconductor memory device according to claim 2, wherein
the memory cell array includes a terrace portion in which the first conductive layer, the second conductive layer, and the third conductive layer are formed in a staircase pattern in the third region, and
the plurality of contact electrodes are connected to the terrace portion.

4. The semiconductor memory device according to claim 2, wherein
each of the plurality of contact electrodes includes:
a columnar conductive layer extending in the first direction; and
an insulating layer that covers a side surface of the conductive column.

5. The semiconductor memory device according to claim 2, wherein
the plurality of conductive layers and the plurality of semiconductor layers are divided in the third direction to constitute a plurality of blocks arranged in the third direction.

6. The semiconductor memory device according to claim 5, wherein
in the first conductive layer, each of the plurality of blocks is further divided in the third direction to constitute a plurality of string units arranged in the third direction.

7. The semiconductor memory device according to claim 5, wherein
respective a part of the plurality of contact electrodes are electrically connected to the second conductive layer and the third conductive layer for the respective blocks.

8. The semiconductor memory device according to claim 6, wherein
respective another part of the plurality of contact electrodes are electrically connected to the first conductive layer for the respective string units.

9. The semiconductor memory device according to claim 1, wherein
the semiconductor substrate includes:
a first circuit that is able to apply different voltages to the first divided layer and the second divided layer and able to apply different voltages to the third divided layer and the fourth divided layer; and
a second circuit that is able to separately read the first wiring and the second wiring.

10. The semiconductor memory device according to claim 6, wherein
the semiconductor substrate includes:
a first circuit that is able to:
apply voltages different for the respective blocks to the plurality of conductive layers;
apply voltages different for the respective string units to the first conductive layer;
apply different voltages to the first divided layer and the second divided layer; and
apply different voltages to the third divided layer and the fourth divided layer; and
a second circuit that is able to separately read the first wiring and the second wiring.

11. A semiconductor memory device comprising:
a semiconductor substrate;
a first memory chip arranged at one side in a first direction intersecting with the semiconductor substrate with respect to the semiconductor substrate; and
a second memory chip arranged at a position farther from the semiconductor substrate than the first memory chip in a first memory chip side of the semiconductor substrate, wherein
the first memory chip includes:
a plurality of first conductive layers extending in a second direction intersecting with the first direction and arranged in the first direction;
a plurality of first semiconductor layers extending in the first direction, arranged in a direction intersecting with the first direction, and facing the plurality of first conductive layers;
respective first gate insulating films provided between the plurality of first semiconductor layers and the plurality of first conductive layers; and
a plurality of first wirings extending in a third direction intersecting with the first direction and the second direction, arranged in the second direction, and electrically connected to one end side in the first direction of the first semiconductor layers,
the second memory chip includes:
a plurality of second conductive layers extending in the second direction and arranged in the first direction;
a plurality of second semiconductor layers extending in the first direction, arranged in a direction intersecting with the first direction, and facing the plurality of second conductive layers;
respective second gate insulating films provided between the plurality of second semiconductor layers and the plurality of second conductive layers; and
a plurality of second wirings extending in the third direction, arranged in the second direction, and electrically connected to one end side in the first direction of the second semiconductor layers,
the first memory chip and the second memory chip include a first region and a second region arranged in the second direction,
the plurality of first conductive layers include:
a third conductive layer closest to the semiconductor substrate;
a fourth conductive layer farthest from the semiconductor substrate; and
a fifth conductive layer provided between the third conductive layer and the fourth conductive layer,
the plurality of second conductive layers include:
a sixth conductive layer closest to the semiconductor substrate;
a seventh conductive layer farthest from the semiconductor substrate; and
an eighth conductive layer provided between the sixth conductive layer and the seventh conductive layer,
the third conductive layer is divided in the second direction to be provided with a first divided layer positioned in the first region and a second divided layer positioned in the second region,
the fourth conductive layer is divided in the second direction to be provided with a third divided layer positioned in the first region and a fourth divided layer positioned in the second region,
the sixth conductive layer is divided in the second direction to be provided with a fifth divided layer positioned in the first region and a sixth divided layer positioned in the second region,
the seventh conductive layer is divided in the second direction to be provided with a seventh divided layer positioned in the first region and an eighth divided layer positioned in the second region,
each of the fifth conductive layer and the eighth conductive layer is continuous over the first region and the second region,
the plurality of first wirings include a third wiring positioned in the first region and a fourth wiring positioned in the second region, and
the plurality of second wirings include a fifth wiring positioned in the first region and a sixth wiring positioned in the second region.

12. The semiconductor memory device according to claim 11, wherein
the first memory chip and the second memory chip include a third region arranged in the second direction with the first region and the second region, and
the first memory chip further includes a plurality of first contact electrodes extending in the first direction in the third region, the plurality of first contact electrodes have respective one ends electrically connected to the first divided layer, the second divided layer, the third divided layer, the fourth divided layer, and the fifth conductive layer, and the plurality of first contact electrodes have the other ends electrically connected to the semiconductor substrate, and
the second memory chip further includes a plurality of second contact electrodes extending in the first direction in the third region, the plurality of second contact electrodes have respective one ends electrically connected to the fifth divided layer, the sixth divided layer, the seventh divided layer, the eighth divided layer, and the eighth conductive layer, and the plurality of second contact electrodes have the other ends electrically connected to the semiconductor substrate via the first memory chip.

13. The semiconductor memory device according to claim 12, wherein
the first memory chip further includes a plurality of third contact electrodes extending in the first direction in the third region, and
respective first contact electrodes electrically connected to the third divided layer, the fourth divided layer, and the fifth conductive layer among the plurality of first contact electrodes are electrically connected to respective second contact electrodes electrically interconnected to the seventh divided layer, the eighth divided layer, and the eighth conductive layer among the plurality of second contact electrodes via the third contact electrodes, respectively.

14. The semiconductor memory device according to claim 13, wherein
second contact electrodes electrically connected to the fifth divided layer and the sixth divided layer among the plurality of second contact electrodes are electrically connected to the semiconductor substrate via the third contact electrodes without being connected to the first divided layer or the second divided layer, and
first contact electrodes connected to the first divided layer and the second divided layer are electrically connected to the semiconductor substrate without being connected to the second contact electrode or the third contact electrode.

15. The semiconductor memory device according to claim 12, wherein
the plurality of first conductive layers and the plurality of first semiconductor layers, and the plurality of second conductive layers and the plurality of second semiconductor layers are each divided in the third direction to constitute a plurality of blocks arranged in the third direction.

16. The semiconductor memory device according to claim 15, wherein
in the third conductive layer and the sixth conductive layer, each of the plurality of blocks is further divided in the third direction to constitute a plurality of string units arranged in the third direction.

17. The semiconductor memory device according to claim 15, wherein
respective a part of the plurality of first contact electrodes are electrically connected to the fourth conductive layer and the fifth conductive layer for the respective blocks, and
respective a part of the plurality of second contact electrodes are electrically connected to the seventh conductive layer and the eighth conductive layer for the respective blocks.

18. The semiconductor memory device according to claim 16, wherein
respective another part of the plurality of first contact electrodes are electrically connected to the third conductive layer for the respective string units, and
respective another part of the plurality of second contact electrodes are electrically connected to the sixth conductive layer for the respective string units.

19. The semiconductor memory device according to claim 15, wherein
the semiconductor substrate includes:
a first circuit that is able to apply different voltages to the first divided layer and the second divided layer, able to apply different voltages to the third divided layer and the fourth divided layer, able to apply different voltages to the fifth divided layer and the sixth divided layer, and able to apply different voltages to the seventh divided layer and the eighth divided layer; and
a second circuit that is able to separately read the third wiring, the fourth wiring, the fifth wiring, and the sixth wiring.

20. The semiconductor memory device according to claim 16, wherein
the semiconductor substrate includes:
a first circuit that is able to:
apply voltages different for the respective blocks to the plurality of first conductive layers and the plurality of second conductive layers;
apply voltages different for the respective string units to the third conductive layer and the sixth conductive layer;
apply different voltages to the first divided layer and the second divided layer;
apply different voltages to the third divided layer and the fourth divided layer;
apply different voltages to the fifth divided layer and the sixth divided layer; and
apply different voltages to the seventh divided layer and the eighth divided layer; and
a second circuit that is able to separately read the third wiring, the fourth wiring, the fifth wiring, and the sixth wiring.
